(19) United States
(12) Patent Application Publication
(10) Pub. No.: US 2026/0367165 A1
(43) Pub. Date: Nov. 19, 2026

(54) SYSTEMS, DEVICES, AND METHODS FOR IMPEDANCE MEASUREMENT OF AN ENERGY SOURCE

(71) Applicant: TAE Technologies, Inc., Foothill Ranch, CA (US)

(72) Inventors: Hessamaldin ABDOLLAHI, Foothill Ranch, CA (US); Mikhail SLEPCHENKOV, Foothill Ranch, CA (US); Arash KHOSHKBAR-SADIGH, Foothill Ranch, CA (US)

(21) Appl. No.: 19/136,494

(22) PCT Filed: Dec. 6, 2023
(86) PCT No.: PCT/US2023/082727

§ 371 Date: Jun. 6, 2025

Related U.S. Application Data
(60) Provisional application No. 63/431,000, filed on Dec. 7, 2022.

(51) Int. Cl. G01R 31/389; G01R 31/36; G01R 31/385; G01R 31/64

(52) U.S. Cl. CPC G01R 31/389; G01R 31/3648; G01R 31/385; G01R 31/64

(57) ABSTRACT

Example embodiments of systems, devices, and methods are provided herein for measuring impedance of an energy source such as a battery or capacitor.

### CROSS-REFERENCE TO RELATED APPLICATIONS

This International Application claims the benefit of U.S. Provisional Application No. 63/431,000, filed Dec. 7, 2022, the content of which is incorporated by reference herein in its entirety and for all purposes.

### FIELD

The subject matter described herein relates generally to systems, devices, and methods for measuring impedance in an energy source such as a battery or capacitor.

### BACKGROUND

In many energy storage applications (e.g., batteries, capacitors, super-capacitors, fuel-cells, and others), an impedance measurement, or a measure of the effective resistance of the component to an alternating current arising from the effects of ohmic resistance and reactance, can be indicative of the internal state, or health, of the energy storage device. Frequently, impedance measurements must be made in an open circuit configuration, and requires installation of special equipment and a time consuming and expensive testing procedure. For example, using an electrochemical impedance spectroscopy (EIS) method typically requires dedicated hardware, including dedicated voltage and current sensors, and are more suited for research and development applications such that they cannot be integrated with a product to measure the impedance of the energy source of the product.

For these and other reasons, needs exist for improved systems, devices, and methods for measuring the impedance of energy sources.

### SUMMARY

Example embodiments of systems, devices, and methods are provided herein for performing impedance measurements of an energy source, e.g., an energy storage device, while the device is online. The impedance measurement can be performed by inserting a perturbation reference, e.g., a broadband perturbation reference, into the control signal that controls switches of a converter that is responsible for charging and/or discharging the energy source. In this way, existing control and operation components used to generate the control signals can be used to generate a perturbation signal that is introduced onto the current of the energy source such that no additional dedicated hardware is required for impedance measurement. As a result, the perturbation signal will appear in the energy source's terminal current. This current and the energy source's terminal voltage are measured and sent to a controller that is configured to determine the impedance based on the current and voltage, e.g., using a Fast Fourier Transform (FFT) based processing method. In another example, the current and voltage measurements can be sent to an external device, e.g., an external server such as a cloud-based server, that determines the impedance. The external device can monitor the state of health (SOH) of the energy source, and many other energy sources, based on impedance measurements for the energy source.

Using a broadband perturbation signal enables the measurement of impedance over many different frequencies. Different types of degradations in an energy source can be detected based on changes in impedance at different frequency bands. Using the broadband perturbation signal enables the measurement of impedance at each frequency band and therefore the detection of the different degradations. The perturbation signal can be injected into multiple control paths to provide a high quality wideband response across a target measurement frequency range to enable accurate impedance measurements throughout the target measurement frequency range.

In some example embodiments, the impedance measurement is performed based on a naturally occurring alternating current (AC) signal imposed on the current of the energy source by the power converter that converts the electrical energy of the energy source for a load and/or the load itself. For example, the converter and/or load can impose harmonic currents onto the energy source current and the harmonic voltage and harmonic current can be measured at the energy source to determine the impedance of the energy source. In this way, the impedance measurements can be generated without injecting a perturbation signal into the system. This technique is particularly advantageous for loads, such as electric vehicles (EVs), that have varying frequency voltages, resulting in harmonic currents having different frequencies. This enables impedance measurements over multiple frequencies and the detection of the different types of degradations.

The described impedance measurement techniques enable the impedance measurements to be taken in an online manner when the energy source is in its actual operational condition and much faster than conventional EIS techniques, such that the status of the energy source can be monitored in real-time and without taking the energy source offline. In addition, no additional hardware, such as perturbation injection hardware, voltage sensors, or current sensors, are required using the described impedance measurement techniques. These advantages (and others) make the described impedance measurement techniques particularly well suited for battery-related diagnosis and prognosis applications for various products, including stationary applications and mobile applications, e.g., for batteries of EVs.

Other systems, devices, methods, features and advantages of the subject matter described herein will be or will become apparent to one with skill in the art upon examination of the following figures and detailed description. It is intended that all such additional systems, methods, features and advantages be included within this description, be within the scope of the subject matter described herein, and be protected by the accompanying claims. In no way should the features of the example embodiments be construed as limiting the appended claims, absent express recitation of those features in the claims.

### BRIEF DESCRIPTION OF FIGURES

The details of the subject matter set forth herein, both as to its structure and operation, may be apparent by study of the accompanying figures, in which like reference numerals refer to like parts. The components in the figures are not necessarily to scale, emphasis instead being placed upon illustrating the principles of the subject matter. Moreover, all illustrations are intended to convey concepts, where relative sizes, shapes and other detailed attributes may be illustrated schematically rather than literally or precisely.

FIGS. 1A-1C are block diagrams depicting example embodiments of a modular energy system.

FIGS. 1D-1E are block diagrams depicting example embodiments of control devices for an energy system.

FIGS. 1F-1G are block diagrams depicting example embodiments of modular energy systems coupled with a load and a charge source.

FIGS. 2A-2B are block diagrams depicting example embodiments of a module and control system within an energy system.

FIG. 2C is a block diagram depicting an example embodiment of a physical configuration of a module.

FIG. 2D is a block diagram depicting an example embodiment of a physical configuration of a modular energy system.

FIGS. 3A-3C are block diagrams depicting example embodiments of modules having various electrical configurations.

FIGS. 4A-4F are schematic views depicting example embodiments of energy sources.

FIGS. 5A-5C are schematic views depicting example embodiments of energy buffers.

FIGS. 6A-6C are schematic views depicting example embodiments of converters.

FIGS. 7A-7E are block diagrams depicting example embodiments of modular energy systems having various topologies.

FIG. 8A is a plot depicting an example output voltage of a module.

FIG. 8B is a plot depicting an example multilevel output voltage of an array of modules.

FIG. 8C is a plot depicting an example reference signal and carrier signals usable in a pulse width modulation control technique.

FIG. 8D is a plot depicting example reference signals and carrier signals usable in a pulse width modulation control technique.

FIG. 8E is a plot depicting example switch signals generated according to a pulse width modulation control technique.

FIG. 8F as a plot depicting an example multilevel output voltage generated by superposition of output voltages from an array of modules under a pulse width modulation control technique.

FIGS. 9A-9B are block diagrams depicting example embodiments of controllers for a modular energy system.

FIG. 10A is a block diagram depicting an example embodiment of a multiphase modular energy system having interconnection module.

FIG. 10B is a schematic diagram depicting an example embodiment of an interconnection module in the multiphase embodiment of FIG. 10A.

FIG. 10C is a block diagram depicting an example embodiment of a modular energy system having two subsystems connected together by interconnection modules.

FIG. 10D is a block diagram depicting an example embodiment of a three-phase modular energy system having interconnection modules supplying auxiliary loads.

FIG. 10E is a schematic view depicting an example embodiment of the interconnection modules in the multiphase embodiment of FIG. 10D.

FIG. 10F is a block diagram depicting another example embodiment of a three-phase modular energy system having interconnection modules supplying auxiliary loads.

FIG. 11 is a block diagram depicting an example embodiment of an energy system having a control system configured to perform online impedance measurement.

FIG. 12A is a block diagram depicting an example embodiment of a perturbation generator.

FIG. 12B is a plot depicting an example frequency response of a perturbation signal.

FIG. 13 is a flowchart illustrating an example embodiment of a method of measuring energy source impedance.

FIG. 14 is a block diagram depicting an example embodiment of an energy system having a control system configured to perform online impedance measurement.

FIG. 15 is a plot depicting an example harmonic voltage and an example harmonic current of an energy source.

FIG. 16 is a flowchart illustrating an example embodiment of a method of measuring energy source impedance.

FIG. 17 is a plot depicting an example impedance vector and phase angle.

FIG. 18 is a plot depicting example energy source impedances.

FIG. 19 is a plot depicting example changes in the capacity of an energy source over time.

FIG. 20 is a flowchart illustrating an example embodiment of a method of generating lookup tables for determining the capacity of an energy source.

FIG. 21 is a flowchart illustrating an example embodiment of a method of determining the state of health (SOH) of an energy source and performing an action based on the SOH.

### DETAILED DESCRIPTION

Before the present subject matter is described in detail, it is to be understood that this disclosure is not limited to the particular embodiments described, as such may, of course, vary. The terminology used herein is for the purpose of describing particular embodiments only, and is not intended to be limiting, since the scope of the present disclosure will be limited only by the appended claims.

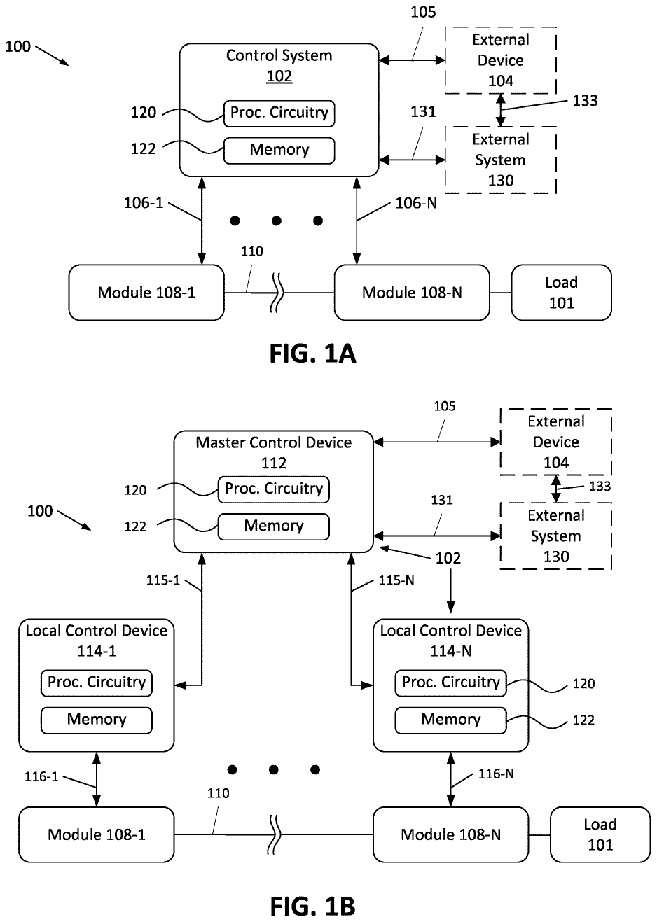

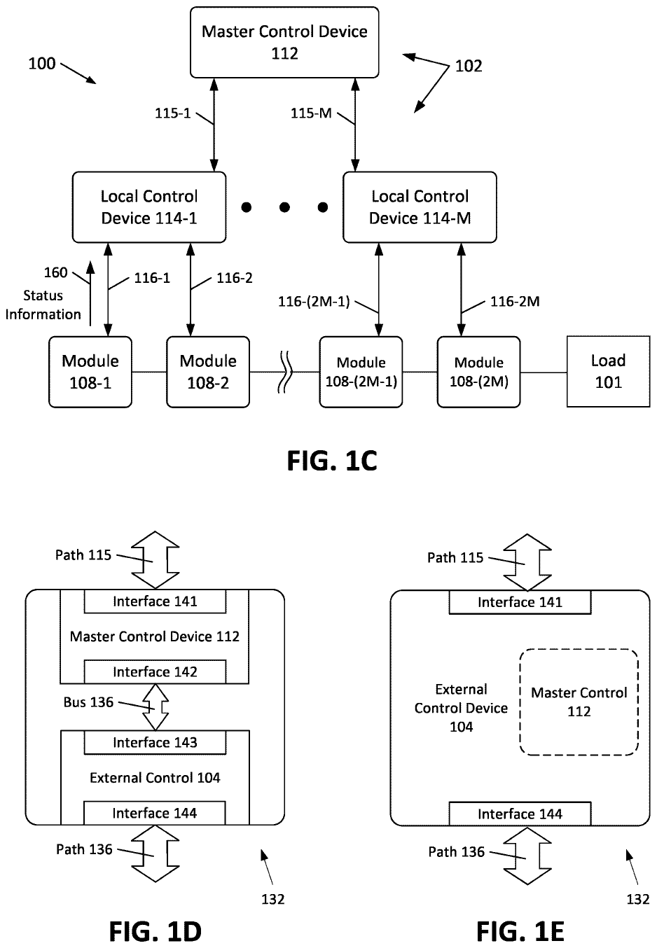

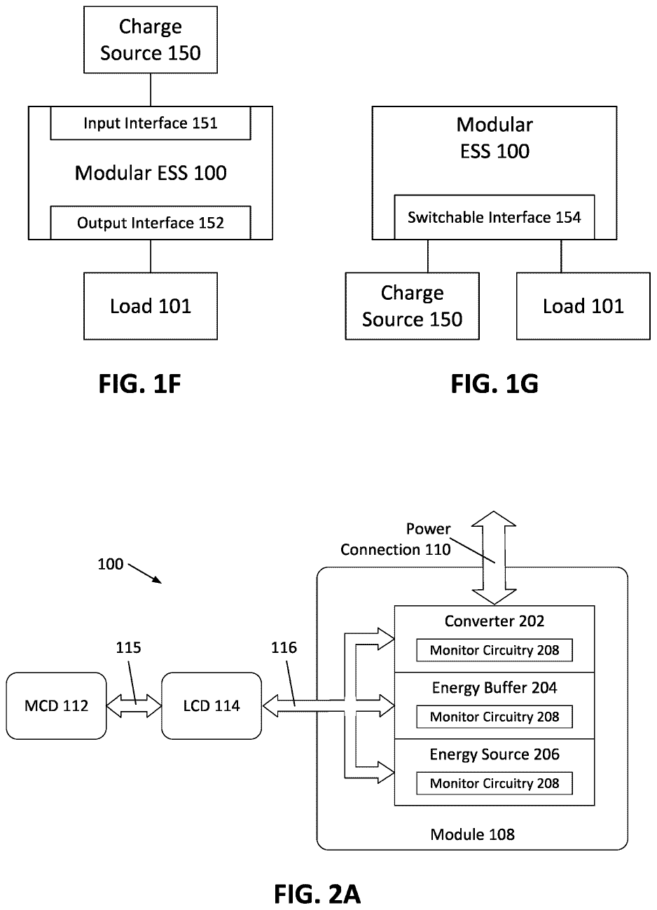

Before describing the example embodiments pertaining to modular energy systems that perform online energy source impedance measurements, it is first useful to describe these underlying systems in greater detail. With reference to FIGS. 1A through 10F, the following sections describe various applications in which embodiments of the modular energy systems can be implemented, embodiments of control systems or devices for the modular energy systems, configurations of the modular energy system embodiments with respect to charging sources and loads, embodiments of individual modules, embodiments of topologies for arrangement of the modules within the systems, embodiments of control methodologies, embodiments of balancing operating characteristics of modules within the systems, and embodiments of the use of interconnection modules.

### Examples of Applications

Stationary applications are those in which the modular energy system is located in a fixed location during use, although it may be capable of being transported to alternative locations when not in use. The module-based energy system resides in a static location while providing electrical energy for consumption by one or more other entities, or storing or buffering energy for later consumption. Examples of stationary applications in which the embodiments disclosed herein can be used include, but are not limited to: energy systems for use by or within one or more residential structures or locales, energy systems for use by or within one or more industrial structures or locales, energy systems for use by or within one or more commercial structures or locales, energy systems for use by or within one or more governmental structures or locales (including both military and non-military uses), energy systems for charging the mobile applications described below (e.g., a charge source or a charging station), and systems that convert solar power, wind, geothermal energy, fossil fuels, or nuclear reactions into electricity for storage. Stationary applications often supply loads such as grids and microgrids, motors, and data centers. A stationary energy system can be used in either a storage or non-storage role.

Mobile applications, sometimes referred to as traction applications, are generally ones where a module-based energy system is located on or within an entity, and stores and provides electrical energy for conversion into motive force by a motor to move or assist in moving that entity. Examples of mobile entities with which the embodiments disclosed herein can be used include, but are not limited to, electric and/or hybrid entities that move over or under land, over or under sea, above and out of contact with land or sea (e.g., flying or hovering in the air), or through outer space. Examples of mobile entities with which the embodiments disclosed herein can be used include, but are not limited to, vehicles, trains, trams, ships, vessels, aircraft, and spacecraft. Examples of mobile vehicles with which the embodiments disclosed herein can be used include, but are not limited to, those having only one wheel or track, those having only two-wheels or tracks, those having only three wheels or tracks, those having only four wheels or tracks, and those having five or more wheels or tracks. Examples of mobile entities with which the embodiments disclosed herein can be used include, but are not limited to, a car, a bus, a truck, a motorcycle, a scooter, an industrial vehicle, a mining vehicle, a flying vehicle (e.g., a plane, a helicopter, a drone, etc.), a maritime vessel (e.g., commercial shipping vessels, ships, yachts, boats or other watercraft), a submarine, a locomotive or rail-based vehicle (e.g., a train, a tram, etc.), a military vehicle, a spacecraft, and a satellite.

In describing embodiments herein, reference may be made to a particular stationary application (e.g., grid, micro-grid, data centers, cloud computing environments) or mobile application (e.g., an electric car). Such references are made for ease of explanation and do not mean that a particular embodiment is limited for use to only that particular mobile or stationary application. Embodiments of systems providing power to a motor can be used in both mobile and stationary applications. While certain configurations may be more suitable to some applications over others, all example embodiments disclosed herein are capable of use in both mobile and stationary applications unless otherwise noted.

### Module-Based Energy System Examples

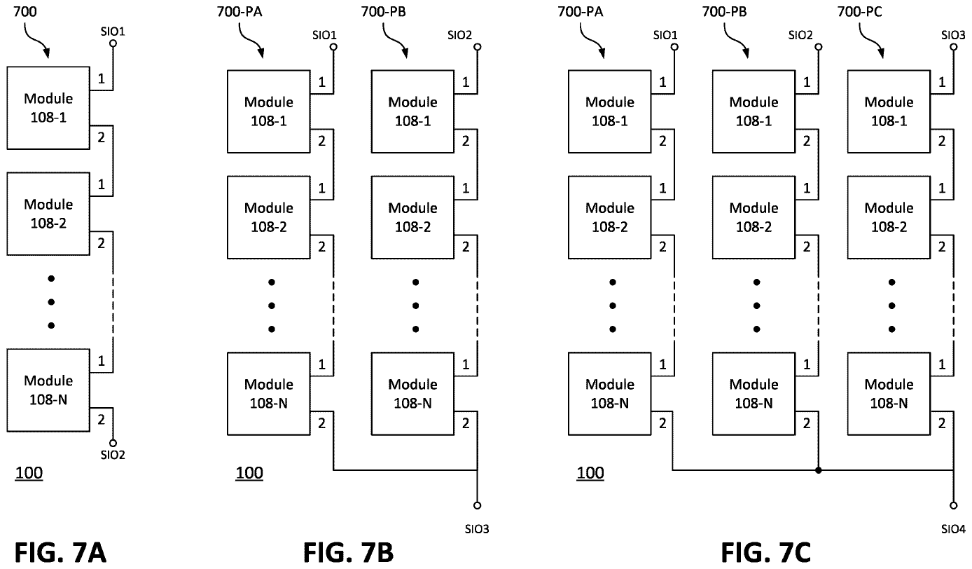

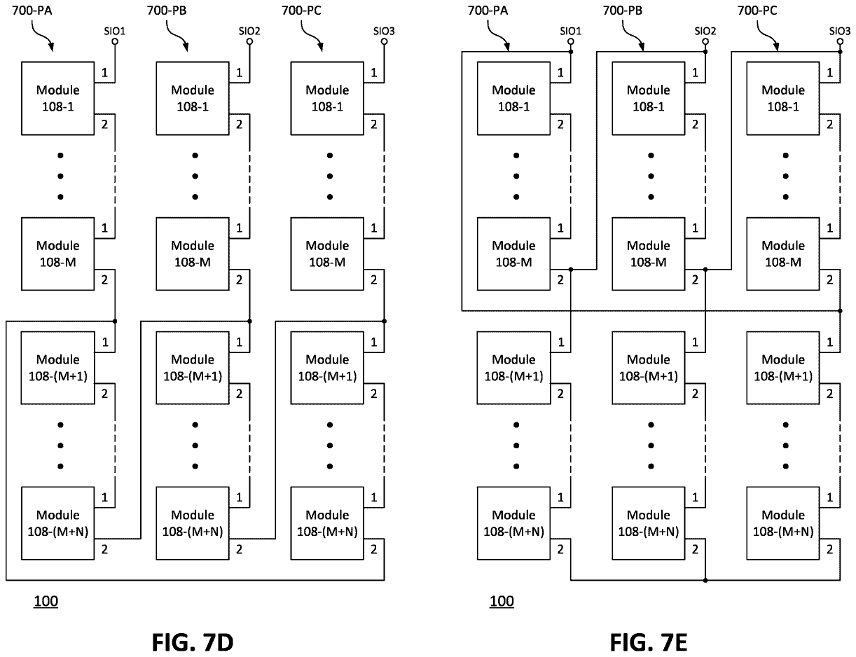

FIG. 1A is a block diagram depicts an example embodiment of a module-based energy system 100. Here, system 100 includes control system 102 communicatively coupled with N converter-source modules 108-1 through 108-N, over communication paths or links 106-1 through 106-N, respectively. Modules 108 are configured to store energy and output the energy as needed to a load 101 (or other modules 108). In these embodiments, any number of two or more modules 108 can be used (e.g., N is greater than or equal to two). Modules 108 can be connected to each other in a variety of manners as will be described in more detail with respect to FIGS. 7A-7E. For ease of illustration, in FIGS. 1A-1C, modules 108 are shown connected in series, or as a one dimensional array, where the Nth module is coupled to load 101.

System 100 is configured to supply power to load 101. Load 101 can be any type of load such as a motor or a grid. System 100 is also configured to store power received from a charge source. FIG. 1F is a block diagram depicting an example embodiment of system 100 with a power input interface 151 for receiving power from a charge source 150 and a power output interface for outputting power to load 101. In this embodiment system 100 can receive and store power over interface 151 at the same time as outputting power over interface 152. FIG. 1G is a block diagram depicting another example embodiment of system 100 with a switchable interface 154. In this embodiment, system 100 can select, or be instructed to select, between receiving power from charge source 150 and outputting power to load 101. System 100 can be configured to supply multiple loads 101, including both primary and auxiliary loads, and/or receive power from multiple charge sources 150 (e.g., a utility-operated power grid and a local renewable energy source (e.g., solar)).

FIG. 1B depicts another example embodiment of system 100. Here, control system 102 is implemented as a master control device (MCD) 112 communicatively coupled with N different local control devices (LCDs) 114-1 through 114-N over communication paths or links 115-1 through 115-N, respectively. Each LCD 114-1 through 114-N is communicatively coupled with one module 108-1 through 108-N over communication paths or links 116-1 through 116-N, respectively, such that there is a 1:1 relationship between LCDs 114 and modules 108.

FIG. 1C depicts another example embodiment of system 100. Here, MCD 112 is communicatively coupled with M different LCDs 114-1 to 114-M over communication paths or links 115-1 to 115-M, respectively. Each LCD 114 can be coupled with and control two or more modules 108. In the example shown here, each LCD 114 is communicatively coupled with two modules 108, such that M LCDs 114-1 to 114-M are coupled with 2M modules 108-1 through 108-2M over communication paths or links 116-1 to 116-2M, respectively.

Control system 102 can be configured as a single device (e.g., FIG. 1A) for the entire system 100 or can be distributed across or implemented as multiple devices (e.g., FIGS. 1B-1C). In some embodiments, control system 102 can be distributed between LCDs 114 associated with the modules 108, such that no MCD 112 is necessary and can be omitted from system 100.

Control system 102 can be configured to execute control using software (instructions stored in memory that are executable by processing circuitry), hardware, or a combination thereof. The one or more devices of control system 102 can each include processing circuitry 120 and memory 122 as shown here. Example implementations of processing circuitry and memory are described further below.

Control system 102 can have a communicative interface for communicating with local devices 104 external to system 100 over a communication link or path 105. For example, control system 102 (e.g., MCD 112) can output data or information about system 100 to another control device 104 (e.g., the Electronic Control Unit (ECU) or Motor Control Unit (MCU) of a vehicle in a mobile application, grid controller in a stationary application, etc.).

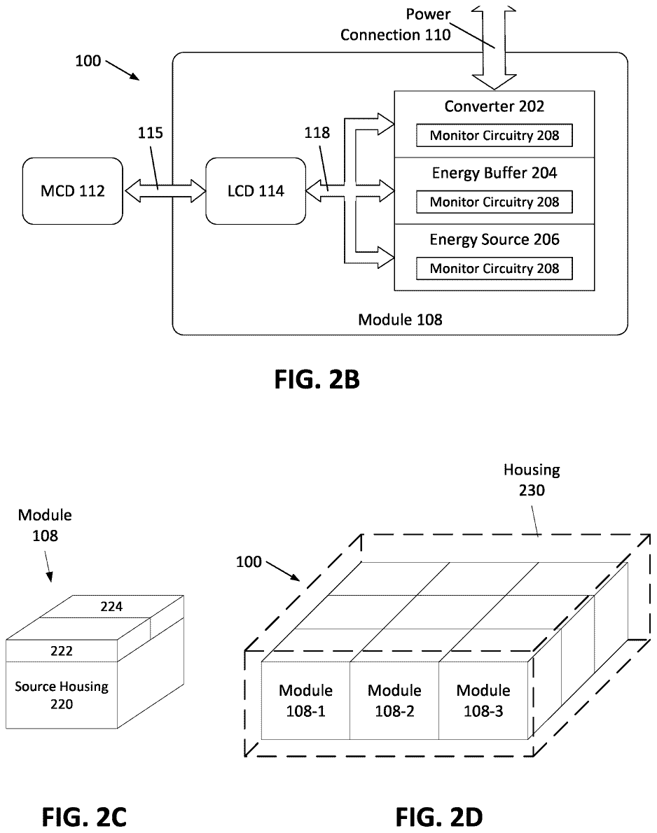

Control system 102 can have a communication interface for communicating with remote systems 130 external to system 100 over a communication link or path 131. For example, control system 102 can output data or information about system 100 to a remote server or system 130, e.g., a cloud-based analysis and/or control system. As described in more detail below, this system can monitor the state of health (SOH) of energy sources 206 (FIG. 2A) based on the received data, e.g., based on impedance data that represents the impedance of the energy source 206.

Local external device 104 can have a communication interface for communicating with remote external system 130 over a communication path or link 133. Similarly, remote external system 130 can include a communication interface for communicating with local external device over communication path or link 133.

Communication paths or links 105, 106, 115, 116, 118 (FIG. 2B), 131, and 133 can each be wired (e.g., electrical, optical) or wireless communication paths that communicate data or information bidirectionally, in parallel or series fashion. Data can be communicated in a standardized (e.g., IEEE, ANSI) or custom (e.g., proprietary) format. In automotive applications, communication paths 115 can be configured to communicate according to FlexRay or CAN protocols. Communication paths 106, 115, 116, and 118 can also provide wired power to directly supply the operating power for system 102 from one or more modules 108. For example, the operating power for each LCD 114 can be supplied only by the one or more modules 108 to which that LCD 114 is connected and the operating power for MCD 112 can be supplied indirectly from one or more of modules 108 (e.g., such as through a car's power network).

Control system 102 is configured to control one or more modules 108 based on status information received from the same or different one or more of modules 108. Control can also be based on one or more other factors, such as requirements of load 101. Controllable aspects include, but are not limited to, one or more of voltage, current, phase, and/or output power of each module 108.

Status information of every module 108 in system 100 can be communicated to control system 102, which can independently control every module 108-1 . . . 108-N. Other variations are possible. For example, a particular module 108 (or subset of modules 108) can be controlled based on status information of that particular module 108 (or subset), based on status information of a different module 108 that is not that particular module 108 (or subset), based on status information of all modules 108 other than that particular module 108 (or subset), based on status information of that particular module 108 (or subset) and status information of at least one other module 108 that is not that particular module 108 (or subset), or based on status information of all modules 108 in system 100.

The status information can be information about one or more aspects, characteristics, or parameters of each module 108. Types of status information include, but are not limited to, the following aspects of a module 108 or one or more components thereof (e.g., energy source, energy buffer, converter, monitor circuitry): State of Charge (SOC) (e.g., the level of charge of an energy source relative to its capacity, such as a fraction or percent) of the one or more energy sources of the module, State of Health (SOH) (e.g., a figure of merit of the condition of an energy source compared to its ideal conditions) of the one or more energy sources of the module, temperature of the one or more energy sources or other components of the module, capacity of the one or more energy sources of the module, voltage of the one or more energy sources and/or other components of the module, current of the one or more energy sources and/or other components of the module, State of Power (SOP) (e.g., the available power limitation of the energy source during discharge and/or charge), State of Energy (SOE) (e.g., the present level of available energy of an energy source relative to the maximum available energy of the source), and/or the presence of absence of a fault in any one or more of the components of the module.

LCDs 114 can be configured to receive the status information from each module 108, or determine the status information from monitored signals or data received from or within each module 108, and communicate that information to MCD 112. In some embodiments, each LCD 114 can communicate raw collected data to MCD 112, which then algorithmically determines the status information on the basis of that raw data. MCD 112 can then use the status information of modules 108 to make control determinations accordingly. The determinations may take the form of instructions, commands, or other information (such as a modulation index described herein) that can be utilized by LCDs 114 to either maintain or adjust the operation of each module 108.

For example, MCD 112 may receive status information and assess that information to determine a difference between at least one module 108 (e.g., a component thereof) and at least one or more other modules 108 (e.g., comparable components thereof). For example, MCD 112 may determine that a particular module 108 is operating with one of the following conditions as compared to one or more other modules 108: with a relatively lower or higher SOC, with a relatively lower or higher SOH, with a relatively lower or higher capacity, with a relatively lower or higher voltage, with a relatively lower or higher current, with a relatively lower or higher temperature, or with or without a fault. In such examples, MCD 112 can output control information that causes the relevant aspect (e.g., output voltage, current, power, temperature) of that particular module 108 to be reduced or increased (depending on the condition). In this manner, the utilization of an outlier module 108 (e.g., operating with a relatively lower SOC or higher temperature), can be reduced so as to cause the relevant parameter of that module 108 (e.g., SOC or temperature) to converge towards that of one or more other modules 108.

The determination of whether to adjust the operation of a particular module 108 can be made by comparison of the status information to predetermined thresholds, limits, or conditions, and not necessarily by comparison to statuses of other modules 108. The predetermined thresholds, limits, or conditions can be static thresholds, limits, or conditions, such as those set by the manufacturer that do not change during use. The predetermined thresholds, limits, or conditions can be dynamic thresholds, limits, or conditions, that are permitted to change, or that do change, during use. For example, MCD 112 can adjust the operation of a module 108 if the status information for that module 108 indicates it to be operating in violation (e.g., above or below) of a predetermined threshold or limit, or outside of a predetermined range of acceptable operating conditions. Similarly, MCD 112 can adjust the operation of a module 108 if the status information for that module 108 indicates the presence of an actual or potential fault (e.g., an alarm, or warning) or indicates the absence or removal of an actual or potential fault. Examples of a fault include, but are not limited to, an actual failure of a component, a potential failure of a component, a short circuit or other excessive current condition, an open circuit, an excessive voltage condition, a failure to receive a communication, the receipt of corrupted data, and the like. Depending on the type and severity of the fault, the faulty module's utilization can be decreased to avoid damaging the module, or the module's utilization can be ceased altogether. For example, if a fault occurs in a given module, then MCD 112 or LCD 114 can cause that module to enter a bypass state as described herein.

MCD 112 can control modules 108 within system 100 to achieve or converge towards a desired target. The target can be, for example, operation of all modules 108 at the same or similar levels with respect to each other, or within predetermined thresholds limits, or conditions. This process is also referred to as balancing or seeking to achieve balance in the operation or operating characteristics of modules 108. The term “balance” as used herein does not require absolute equality between modules 108 or components thereof, but rather is used in a broad sense to convey that operation of system 100 can be used to actively reduce disparities in operation (or operative state) between modules 108 that would otherwise exist.

MCD 112 can communicate control information to LCD 114 for the purpose of controlling the modules 108 associated with the LCD 114. The control information can be, e.g., a modulation index and a reference signal as described herein, a modulated reference signal, or otherwise. Each LCD 114 can use (e.g., receive and process) the control information to generate switch signals that control operation of one or more components (e.g., a converter) within the associated module(s) 108. In some embodiments, MCD 112 generates the switch signals directly and outputs them to LCD 114, which relays the switch signals to the intended module component.

All or a portion of control system 102 can be combined with a local system external control device 104 that controls one or more other aspects of the mobile or stationary application. When integrated in this shared or common control device (or subsystem), control of system 100 can be implemented in any desired fashion, such as one or more software applications executed by processing circuitry of the shared device, with hardware of the shared device, or a combination thereof. Non-exhaustive examples of local external control devices 104 include: a vehicular ECU or MCU having control capability for one or more other vehicular functions (e.g., motor control, driver interface control, traction control, etc.); a grid or micro-grid controller having responsibility for one or more other power management functions (e.g., load interfacing, load power requirement forecasting, transmission and switching, interface with charge sources (e.g., diesel, solar, wind), charge source power forecasting, back up source monitoring, asset dispatch, etc.); and a data center control subsystem (e.g., environmental control, network control, backup control, etc.).

FIGS. 1D and 1E are block diagrams depicting example embodiments of a shared or common control device (or system) 132 in which control system 102 can be implemented. In FIG. 1D, common control device 132 includes master control device 112 and local external control device 104. Master control device 112 includes an interface 141 for communication with LCDs 114 over path 115, as well as an interface 142 for communication with local external control device 104 over internal communication bus 136. Local external control device 104 includes an interface 143 for communication with master control device 112 over bus 136, and an interface 144 for communication with other entities (e.g., components of the vehicle or grid) of the overall application over communication path 136. In some embodiments, common control device 132 can be integrated as a common housing or package with devices 112 and 104 implemented as discrete integrated circuit (IC) chips or packages contained therein.

In FIG. 1E, local external control device 104 acts as common control device 132, with the master control functionality implemented as a component within device 104. This component 112 can be or include software or other program instructions stored and/or hardcoded within memory of device 104 and executed by processing circuitry thereof. The component can also contain dedicated hardware. The component can be a self-contained module or core, with one or more internal hardware and/or software interfaces (e.g., application program interface (API)) for communication with the operating software of local external control device 104. Local external control device 104 can manage communication with LCDs 114 over interface 141 and other devices over interface 144. In various embodiments, device 104/132 can be integrated as a single IC chip, can be integrated into multiple IC chips in a single package, or integrated as multiple semiconductor packages within a common housing.

In the embodiments of FIGS. 1D and 1E, the master control functionality of system 102 is shared in common device 132, however, other divisions of shared control or permitted. For example, part of the master control functionality can be distributed between common device 132 and a dedicated MCD 112. In another example, both the master control functionality and at least part of the local control functionality can be implemented in common device 132 (e.g., with remaining local control functionality implemented in LCDs 114). In some embodiments, all of control system 102 is implemented in common device (or subsystem) 132. In some embodiments, local control functionality is implemented within a device shared with another component of each module 108, such as a Battery Management System (BMS).

### Examples of Modules within Cascaded Energy Systems

Module 108 can include one or more energy sources and a power electronics converter and, if desired, an energy buffer. FIGS. 2A-2B are block diagrams depicting additional example embodiments of system 100 with module 108 having a power converter 202, an energy buffer 204, and an energy source 206. Converter 202 can be a voltage converter or a current converter. The embodiments are described herein with reference to voltage converters, although the embodiments are not limited to such. Converter 202 can be configured to convert a direct current (DC) signal from energy source 204 into an alternating current (AC) signal and output it over power connection 110 (e.g., an inverter). Converter 202 can also receive an AC or DC signal over connection 110 and apply it to energy source 204 with either polarity in a continuous or pulsed form. Converter 202 can be or include an arrangement of switches (e.g., power transistors) such as a half bridge of full bridge (H-bridge). In some embodiments converter 202 includes only switches and the converter (and the module as a whole) does not include a transformer.

Converter 202 can be also (or alternatively) be configured to perform AC to DC conversion (e.g., a rectifier) such as to charge a DC energy source from an AC source, DC to DC conversion, and/or AC to AC conversion (e.g., in combination with an AC-DC converter). In some embodiments, such as to perform AC-AC conversion, converter 202 can include a transformer, either alone or in combination with one or more power semiconductors (e.g., switches, diodes, thyristors, and the like). In other embodiments, such as those where weight and cost is a significant factor, converter 202 can be configured to perform the conversions with only power switches, power diodes, or other semiconductor devices and without a transformer.

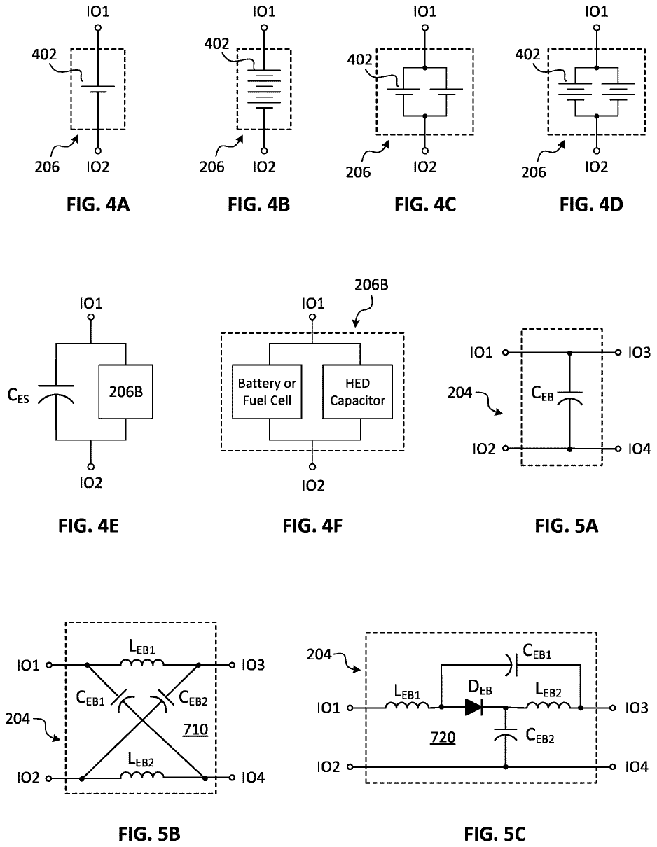

Energy source 206 is preferably a robust energy storage device capable of outputting direct current and having an energy density suitable for energy storage applications for electrically powered devices. Energy source 206 can be an electrochemical battery, such as a single battery cell or multiple battery cells connected together in a battery module or array, or any combination thereof. FIGS. 4A-4D are schematic diagrams depicting example embodiments of energy source 206 configured as a single battery cell 402 (FIG. 4A), a battery module with a series connection of multiple (e.g., four) cells 402 (FIG. 4B), a battery module with a parallel connection of single cells 402 (FIG. 4C), and a battery module with a parallel connection with legs having two cells 402 each (FIG. 4D). A non-exhaustive list of examples of battery types is set forth elsewhere herein.

Energy source 206 can also be a high energy density (HED) capacitor, such as an ultracapacitor or supercapacitor. An HED capacitor can be configured as a double layer capacitor (electrostatic charge storage), pseudocapacitor (electrochemical charge storage), hybrid capacitor (electrostatic and electrochemical), or otherwise, as opposed to a solid dielectric type of a typical electrolytic capacitor. The HED capacitor can have an energy density of 10 to 100 times (or higher) that of an electrolytic capacitor, in addition to a higher capacity. For example, HED capacitors can have a specific energy greater than 1.0 watt hours per kilogram (Wh/kg), and a capacitance greater than 10-100 farads (F). As with the batteries described with respect to FIGS. 4A-4D, energy source 206 can be configured as a single HED capacitor or multiple HED capacitors connected together in an array (e.g., series, parallel, or a combination thereof).

Energy source 206 can also be a fuel cell. The fuel cell can be a single fuel cell, multiple fuel cells connected in series or parallel, or a fuel cell module. Examples of fuel cell types include proton-exchange membrane fuel cells (PEMFC), phosphoric acid fuel cells (PAFC), solid acid fuel cells, alkaline fuel cells, high temperature fuel cells, solid oxide fuel cells, molten electrolyte fuel cells, and others. As with the batteries described with respect to FIGS. 4A-4D, energy source 206 can be configured as a single fuel cell or multiple fuel cells connected together in an array (e.g., series, parallel, or a combination thereof). The aforementioned examples of source classes (e.g., batteries, capacitors, and fuel cells) and types (e.g., chemistries and/or structural configurations within each class) are not intended to form an exhaustive list, and those of ordinary skill in the art will recognize other variants that fall within the scope of the present subject matter.

Energy buffer 204 can dampen or filter fluctuations in current across the DC line or link (e.g., +V_{DCL} and −V_{DCL} as described below), to assist in maintaining stability in the DC link voltage. These fluctuations can be relatively low (e.g., kilohertz) or high (e.g., megahertz) frequency fluctuations or harmonics caused by the switching of converter 202, or other transients. These fluctuations can be absorbed by buffer 204 instead of being passed to source 206 or to ports IO3 and IO4 of converter 202.

Power connection 110 is a connection for transferring energy or power to, from and through module 108. Module 108 can output energy from energy source 206 to power connection 110, where it can be transferred to other modules of the system or to a load. Module 108 can also receive energy from other modules 108 or a charging source (DC charger, single phase charger, multi-phase charger). Signals can also be passed through module 108 bypassing energy source 206. The routing of energy or power into and out of module 108 is performed by converter 202 under the control of LCD 114 (or another entity of system 102).

In the embodiment of FIG. 2A, LCD 114 is implemented as a component separate from module 108 (e.g., not within a shared module housing) and is connected to and capable of communication with converter 202 via communication path 116. In the embodiment of FIG. 2B, LCD 114 is included as a component of module 108 and is connected to and capable of communication with converter 202 via internal communication path 118 (e.g., a shared bus or discrete connections). LCD 114 can also be capable of receiving signals from, and transmitting signals to, energy buffer 204 and/or energy source 206 over paths 116 or 118.

Module 108 can also include monitor circuitry 208 configured to monitor (e.g., collect, sense, measure, and/or determine) one or more aspects of module 108 and/or the components thereof, such as voltage, current, temperature or other operating parameters that constitute status information (or can be used to determine status information by, e.g., LCD 114). A main function of the status information is to describe the state of the one or more energy sources 206 of the module 108 to enable determinations as to how much to utilize the energy source in comparison to other sources in system 100, although status information describing the state of other components (e.g., voltage, temperature, and/or presence of a fault in buffer 204, temperature and/or presence of a fault in converter 202, presence of a fault elsewhere in module 108, etc.) can be used in the utilization determination as well. Monitor circuitry 208 can include one or more sensors, shunts, dividers, fault detectors, Coulomb counters, controllers or other hardware and/or software configured to monitor such aspects. Monitor circuitry 208 can be separate from the various components 202, 204, and 206, or can be integrated with each component 202, 204, and 206 (as shown in FIGS. 2A-2B), or any combination thereof. In some embodiments, monitor circuitry 208 can be part of or shared with a Battery Management System (BMS) for a battery energy source 204. Discrete circuitry is not needed to monitor each type of status information, as more than one type of status information can be monitored with a single circuit or device, or otherwise algorithmically determined without the need for additional circuits.

LCD 114 can receive status information (or raw data) about the module components over communication paths 116, 118. LCD 114 can also transmit information to module components over paths 116, 118. Paths 116 and 118 can include diagnostics, measurement, protection, and control signal lines. The transmitted information can be control signals for one or more module components. The control signals can be switch signals for converter 202 and/or one or more signals that request the status information from module components. For example, LCD 114 can cause the status information to be transmitted over paths 116, 118 by requesting the status information directly, or by applying a stimulus (e.g., voltage) to cause the status information to be generated, in some cases in combination with switch signals that place converter 202 in a particular state.

The physical configuration or layout of module 108 can take various forms. In some embodiments, module 108 can include a common housing in which all module components, e.g., converter 202, buffer 204, and source 206, are housed, along with other optional components such as an integrated LCD 114. In other embodiments, the various components can be separated in discrete housings that are secured together. FIG. 2C is a block diagram depicting an example embodiment of a module 108 having a first housing 220 that holds an energy source 206 of the module and accompanying electronics such as monitor circuitry, a second housing 222 that holds module electronics such as converter 202, energy buffer 204, and other accompany electronics such as monitor circuitry, and a third housing 224 that holds LCD 114 (not shown) for the module 108. In alternative embodiments the module electronics and LCD 114 can be housed within the same single housing. In still other embodiments, the module electronics, LCD 114, and energy source(s) can be housed within the same single housing for the module 108. Electrical connections between the various module components can proceed through the housings 220, 222, 224 and can be exposed on any of the housing exteriors for connection with other devices such as other modules 108 or MCD 112.

Modules 108 of system 100 can be physically arranged with respect to each other in various configurations that depend on the needs of the application and the number of loads. For example, in a stationary application where system 100 provides power for a microgrid, modules 108 can be placed in one or more racks or other frameworks. Such configurations may be suitable for larger mobile applications as well, such as maritime vessels. Alternatively, modules 108 can be secured together and located within a common housing, referred to as a pack. A rack or a pack may have its own dedicated cooling system shared across all modules. Pack configurations are useful for smaller mobile applications such as electric cars. System 100 can be implemented with one or more racks (e.g., for parallel supply to a microgrid) or one or more packs (e.g., serving different motors of the vehicle), or combination thereof. FIG. 2D is a block diagram depicting an example embodiment of system 100 configured as a pack with nine modules 108 electrically and physically coupled together within a common housing 230.

Examples of these and further configurations are described in Int'l. Appl. No. PCT/US20/25366, filed Mar. 27, 2020 and titled Module-Based Energy Systems Capable of Cascaded and Interconnected Configurations, and Methods Related Thereto, which is incorporated by reference herein in its entirety for all purposes.

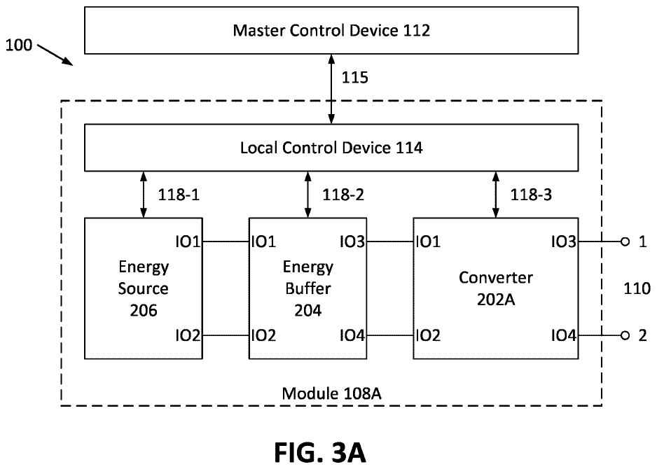

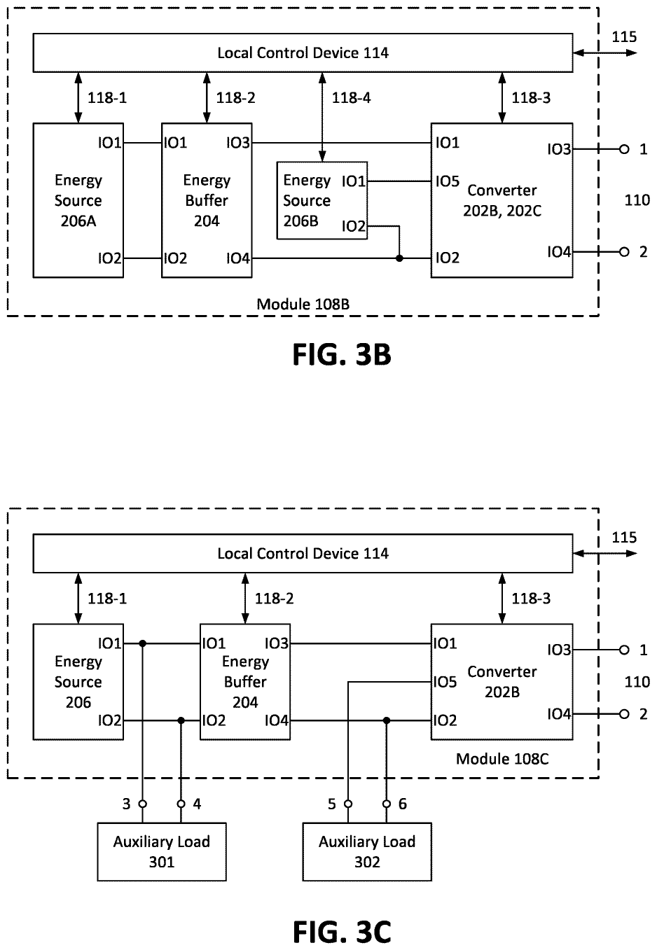

FIGS. 3A-3C are block diagrams depicting example embodiments of modules 108 having various electrical configurations. These embodiments are described as having one LCD 114 per module 108, with the LCD 114 housed within the associated module, but can be configured otherwise as described herein. FIG. 3A depicts a first example configuration of a module 108A within system 100. Module 108A includes energy source 206, energy buffer 204, and converter 202A. Each component has power connection ports (e.g., terminals, connectors) into which power can be input and/or from which power can be output, referred to herein as IO ports. Such ports can also be referred to as input ports or output ports depending on the context.

Energy source 206 can be configured as any of the energy source types described herein (e.g., a battery as described with respect to FIGS. 4A-4D, an HED capacitor, a fuel cell, or otherwise). Ports IO1 and 102 of energy source 206 can be connected to ports IO1 and IO2, respectively, of energy buffer 204. Energy buffer 204 can be configured to buffer or filter high and low frequency energy pulsations arriving at buffer 204 through converter 202, which can otherwise degrade the performance of module 108. The topology and components for buffer 204 are selected to accommodate the maximum permissible amplitude of these high frequency voltage pulsations. Several (non-exhaustive) example embodiments of energy buffer 204 are depicted in the schematic diagrams of FIGS. 5A-5C. In FIG. 5A, buffer 204 is an electrolytic and/or film capacitor C_{EB}, in FIG. 5B buffer 204 is a Z-source network 710, formed by two inductors L_{EB1} and L_{EB2} and two electrolytic and/or film capacitors C_{EB1} and C_{EB2}, and in FIG. 5C buffer 204 is a quasi Z-source network 720, formed by two inductors L_{EB1} and L_{EB2}, two electrolytic and/or film capacitors C_{EB1} and C_{EB2} and a diode DEB.

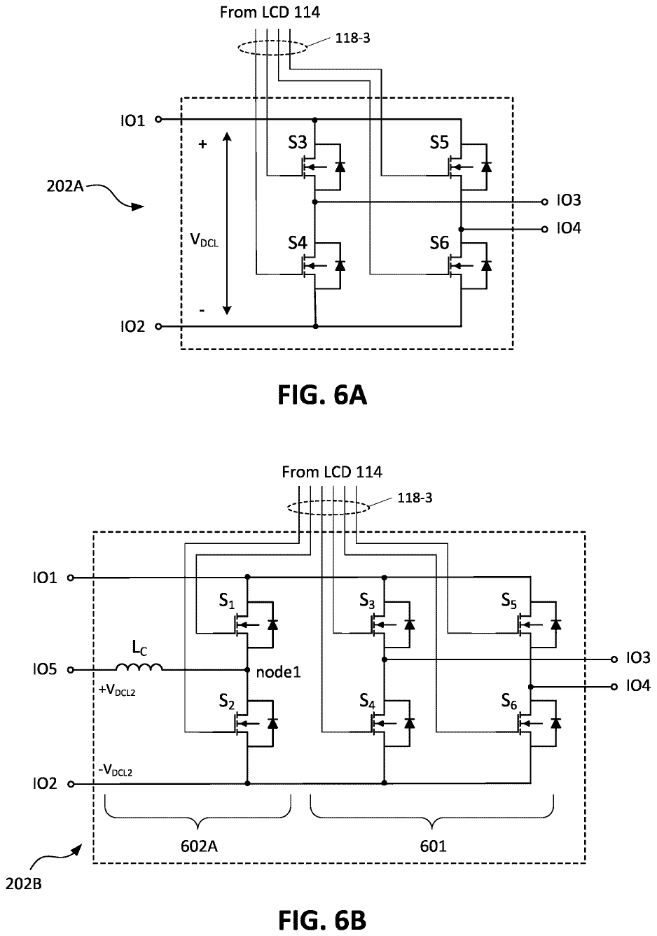

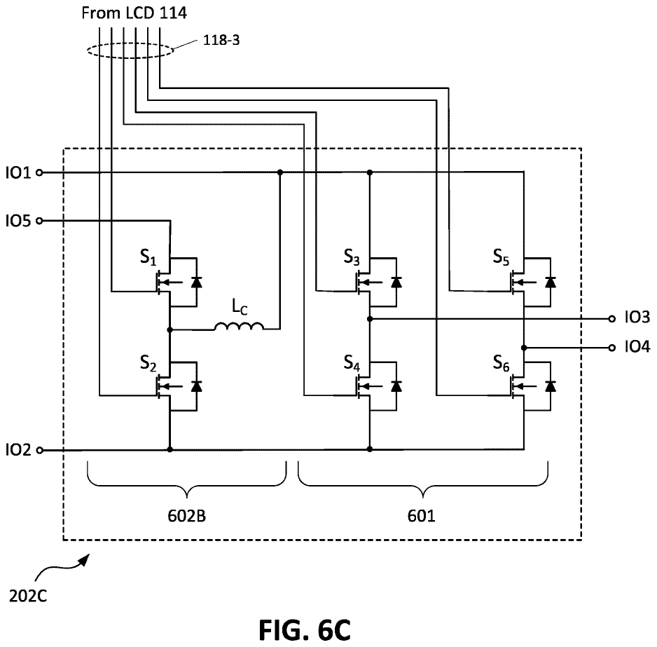

Ports IO3 and IO4 of energy buffer 204 can be connected to ports IO1 and IO2, respectively, of converter 202A, which can be configured as any of the power converter types described herein. FIG. 6A is a schematic diagram depicting an example embodiment of converter 202A configured as a DC-AC converter that can receive a DC voltage at ports IO1 and IO2 and switch to generate pulses at ports IO3 and IO4. Converter 202A can include multiple switches, and here converter 202A includes four switches S3, S4, S5, S6 arranged in a full bridge configuration. Control system 102 or LCD 114 can independently control each switch via control input lines 118-3 to each gate.

The switches can be any suitable switch type, such as power semiconductors like the metal-oxide-semiconductor field-effect transistors (MOSFETs) shown here, insulated gate bipolar transistors (IGBTs), or gallium nitride (GaN) transistors. Semiconductor switches can operate at relatively high switching frequencies, thereby permitting converter 202 to be operated in pulse-width modulated (PWM) mode if desired, and to respond to control commands within a relatively short interval of time. This can provide a high tolerance of output voltage regulation and fast dynamic behavior in transient modes.

In this embodiment, a DC line voltage V_{DCL} can be applied to converter 202 between ports IO1 and IO2. By connecting V_{DCL} to ports IO3 and IO4 by different combinations of switches S3, S4, S5, S6, converter 202 can generate three different voltage outputs at ports IO3 and IO4: +V_{DCL}, 0, and −V_{DCL}. A switch signal provided to each switch controls whether the switch is on (closed) or off (open). To obtain +V_{DCL}, switches S3 and S6 are turned on while S4 and S5 are turned off, whereas −V_{DCL} can be obtained by turning on switches S4 and S5 and turning off S3 and S6. The output voltage can be set to zero (including near zero) or a reference voltage by turning on S3 and S5 with S4 and S6 off, or by turning on S4 and S6 with S3 and S5 off. These voltages can be output from module 108 over power connection 110. Ports IO3 and IO4 of converter 202 can be connected to (or form) module IO ports 1 and 2 of power connection 110, so as to generate the output voltage for use with output voltages from other modules 108.

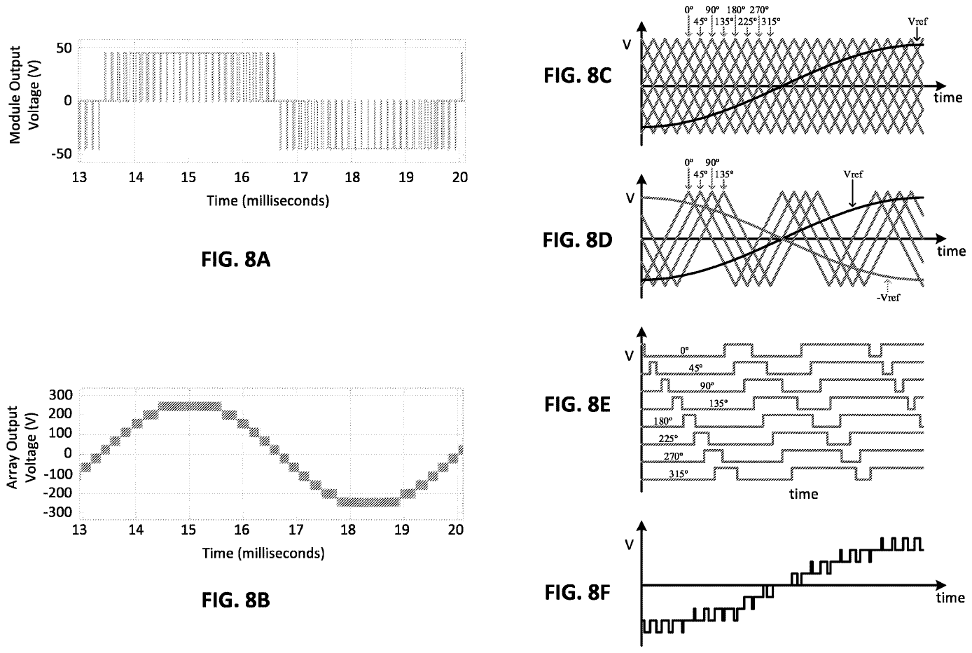

The control or switch signals for the embodiments of converter 202 described herein can be generated in different ways depending on the control technique utilized by system 100 to generate the output voltage of converter 202. In some embodiments, the control technique is a PWM technique such as space vector pulse-width modulation (SVPWM) or sinusoidal pulse-width modulation (SPWM), or variations thereof. FIG. 8A is a graph of voltage versus time depicting an example of an output voltage waveform 802 of converter 202. For ease of description, the embodiments herein will be described in the context of a PWM control technique, although the embodiments are not limited to such. Other classes of techniques can be used. One alternative class is based on hysteresis, examples of which are described in Int'l Publ. Nos. WO 2018/231810A1, WO 2018/232403A1, and WO 2019/183553A1, which are incorporated by reference herein for all purposes.

Each module 108 can be configured with multiple energy sources 206 (e.g., two, three, four, or more). Each energy source 206 of module 108 can be controllable (switchable) to supply power to connection 110 (or receive power from a charge source) independent of the other sources 206 of the module. For example, all sources 206 can output power to connection 110 (or be charged) at the same time, or only one (or a subset) of sources 206 can supply power (or be charged) at any one time. In some embodiments, the sources 206 of the module can exchange energy between them, e.g., one source 206 can charge another source 206. Each of the sources 206 can be configured as any energy source described herein (e.g., battery, HED capacitor, fuel cell). Each of the sources 206 can be the same class (e.g., each can be a battery, each can be an HED capacitor, or each can be a fuel cell), or a different class (e.g., a first source can be a battery and a second source can be an HED capacitor or fuel cell, or a first source can be an HED capacitor and a second source can be a fuel cell).

FIG. 3B is a block diagram depicting an example embodiment of a module 108B in a dual energy source configuration with a primary energy source 206A and secondary energy source 206B. Ports IO1 and IO2 of primary source 202A can be connected to ports IO1 and IO2 of energy buffer 204. Module 108B includes a converter 202B having an additional IO port. Ports IO3 and IO4 of buffer 204 can be connected ports IO1 and IO2, respectively, of converter 202B. Ports IO1 and IO2 of secondary source 206B can be connected to ports IO5 and IO2, respectively, of converter 202B (also connected to port 104 of buffer 204).

In this example embodiment of module 108B, primary energy source 202A, along with the other modules 108 of system 100, supplies the average power needed by the load. Secondary source 202B can serve the function of assisting energy source 202 by providing additional power at load power peaks, or absorbing excess power, or otherwise.

As mentioned both primary source 206A and secondary source 206B can be utilized simultaneously or at separate times depending on the switch state of converter 202B. If at the same time, an electrolytic and/or a film capacitor (CES) can be placed in parallel with source 206B as depicted in FIG. 4E to act as an energy buffer for the source 206B, or energy source 206B can be configured to utilize an HED capacitor in parallel with another energy source (e.g., a battery or fuel cell) as depicted in FIG. 4F.

FIGS. 6B and 6C are schematic views depicting example embodiments of converters 202B and 202C, respectively. Converter 202B includes switch circuitry portions 601 and 602A. Portion 601 includes switches S3 through S6 configured as a full bridge in similar manner to converter 202A, and is configured to selectively couple IO1 and IO2 to either of IO3 and IO4, thereby changing the output voltages of module 108B. Portion 602A includes switches S1 and S2 configured as a half bridge and coupled between ports IO1 and IO2. A coupling inductor Lc is connected between port 105 and a node1 present between switches S1 and S2 such that switch portion 602A is a bidirectional converter that can regulate (boost or buck) voltage (or inversely current). Switch portion 602A can generate two different voltages at node1, which are +V_{DCL2} and 0, referenced to port IO2, which can be at virtual zero potential. The current drawn from or input to energy source 202B can be controlled by regulating the voltage on coupling inductor Lc, using, for example, a pulse-width modulation technique or a hysteresis control method for commutating switches S1 and S2. Other techniques can also be used.

Converter 202C differs from that of 202B as switch portion 602B includes switches S1 and S2 configured as a half bridge and coupled between ports IO5 and IO2. A coupling inductor Lc is connected between port IO1 and a node1 present between switches S1 and S2 such that switch portion 602B is configured to regulate voltage.

Control system 102 or LCD 114 can independently control each switch of converters 202B and 202C via control input lines 118-3 to each gate. In these embodiments and that of FIG. 6A, LCD 114 (not MCD 112) generates the switching signals for the converter switches. Alternatively, MCD 112 can generate the switching signals, which can be communicated directly to the switches, or relayed by LCD 114. In some embodiments, driver circuitry for generating the switching signals can be present in or associated with MCD 112 and/or LCD 114.

The aforementioned zero voltage configuration for converter 202 (turning on S3 and S5 with S4 and S6 off, or turning on S4 and S6 with S3 and S5 off) can also be referred to as a bypass state for the given module. This bypass state can be entered if a fault is detected in the given module, or if a system fault is detected warranting shut-off of more than one (or all modules) in an array or system. A fault in the module can be detected by LCD 114 and the control switching signals for converter 202 can be set to engage the bypass state without intervention by MCD 112. Alternatively, fault information for a given module can be communicated by LCD 114 to MCD 112, and MCD 112 can then make a determination whether to engage the bypass state, and if so, can communicate instructions to engage the bypass state to the LCD 114 associated with the module having the fault, at which point LCD 114 can output switching signals to cause engagement of the bypass state.

In embodiments where a module 108 includes three or more energy sources 206, converters 202B and 202C can be scaled accordingly such that each additional energy source 206B is coupled to an additional IO port leading to an additional switch circuitry portion 602A or 602B, depending on the needs of the particular source. For example a dual source converter 202 can include both switch portions 202A and 202B.

Modules 108 with multiple energy sources 206 are capable of performing additional functions such as energy sharing between sources 206, energy capture from within the application (e.g., regenerative braking), charging of the primary source by the secondary source even while the overall system is in a state of discharge, and active filtering of the module output. The active filtering function can also be performed by modules having a typical electrolytic capacitor instead of a secondary energy source. Examples of these functions are described in more detail in Int'l. Appl. No. PCT/US20/25366, filed Mar. 27, 2020 and titled Module-Based Energy Systems Capable of Cascaded and Interconnected Configurations, and Methods Related Thereto, and Int′1. Publ. No. WO 2019/183553, filed Mar. 22, 2019, and titled Systems and Methods for Power Management and Control, both of which are incorporated by reference herein in their entireties for all purposes.

Each module 108 can be configured to supply one or more auxiliary loads with its one or more energy sources 206. Auxiliary loads are loads that require lower voltages than the primary load 101. Examples of auxiliary loads can be, for example, an on-board electrical network of an electric vehicle, or an HVAC system of an electric vehicle. The load of system 100 can be, for example, one of the phases of the electric vehicle motor or electrical grid. This embodiment can allow a complete decoupling between the electrical characteristics (terminal voltage and current) of the energy source and those of the loads.

FIG. 3C is a block diagram depicting an example embodiment of a module 108C configured to supply power to a first auxiliary load 301 and a second auxiliary load 302, where module 108C includes an energy source 206, energy buffer 204, and converter 202B coupled together in a manner similar to that of FIG. 3B. First auxiliary load 301 requires a voltage equivalent to that supplied from source 206. Load 301 is coupled to IO ports 3 and 4 of module 108C, which are in turn coupled to ports IO1 and IO2 of source 206. Source 206 can output power to both power connection 110 and load 301. Second auxiliary load 302 requires a constant voltage lower than that of source 206. Load 302 is coupled to IO ports 5 and 6 of module 108C, which are coupled to ports 105 and IO2, respectively, of converter 202B. Converter 202B can include switch portion 602 having coupling inductor Lc coupled to port IO5 (FIG. 6B). Energy supplied by source 206 can be supplied to load 302 through switch portion 602 of converter 202B. It is assumed that load 302 has an input capacitor (a capacitor can be added to module 108C if not), so switches S1 and S2 can be commutated to regulate the voltage on and current through coupling inductor Lc and thus produce a stable constant voltage for load 302. This regulation can step down the voltage of source 206 to the lower magnitude voltage is required by load 302.

Module 108C can thus be configured to supply one or more first auxiliary loads in the manner described with respect to load 301, with the one or more first loads coupled to IO ports 3 and 4. Module 108C can also be configured to supply one or more second auxiliary loads in the manner described with respect to load 302. If multiple second auxiliary loads 302 are present, then for each additional load 302 module 108C can be scaled with additional dedicated module output ports (like 5 and 6), an additional dedicated switch portion 602, and an additional converter IO port coupled to the additional portion 602.

Energy source 206 can thus supply power for any number of auxiliary loads (e.g., 301 and 302), as well as the corresponding portion of system output power needed by primary load 101. Power flow from source 206 to the various loads can be adjusted as desired.

Module 108 can be configured as needed with two or more energy sources 206 (FIG. 3B) and to supply first and/or second auxiliary loads (FIG. 3C) through the addition of a switch portion 602 and converter port IO5 for each additional source 206B or second auxiliary load 302. Additional module IO ports (e.g., 3, 4, 5, 6) can be added as needed. Module 108 can also be configured as an interconnection module to exchange energy (e.g., for balancing) between two or more arrays, two or more packs, or two or more systems 100 as described further herein. This interconnection functionality can likewise be combined with multiple source and/or multiple auxiliary load supply capabilities.

Control system 102 can perform various functions with respect to the components of modules 108A, 108B, and 108C. These functions can include management of the utilization (amount of use) of each energy source 206, protection of energy buffer 204 from over-current, over-voltage and high temperature conditions, and control and protection of converter 202.

For example, to manage (e.g., adjust by increasing, decreasing, or maintaining) utilization of each energy source 206, LCD 114 can receive one or more monitored voltages, temperatures, and currents from each energy source 206 (or monitor circuitry). The monitored voltages can be at least one of, preferably all, voltages of each elementary component independent of the other components (e.g., each individual battery cell, HED capacitor, and/or fuel cell) of the source 206, or the voltages of groups of elementary components as a whole (e.g., voltage of the battery array, HED capacitor array, and/or fuel cell array). Similarly the monitored temperatures and currents can be at least one of, preferably all, temperatures and currents of each elementary component independent of the other components of the source 206, or the temperatures and currents of groups of elementary components as a whole, or any combination thereof. The monitored signals can be status information, with which LCD 114 can perform one or more of the following: calculation or determination of a real capacity, actual State of Charge (SOC) and/or State of Health (SOH) of the elementary components or groups of elementary components; set or output a warning or alarm indication based on monitored and/or calculated status information; and/or transmission of the status information to MCD 112. LCD 114 can receive control information (e.g., a modulation index, synchronization signal) from MCD 112 and use this control information to generate switch signals for converter 202 that manage the utilization of the source 206.

To protect energy buffer 204, LCD 114 can receive one or more monitored voltages, temperatures, and currents from energy buffer 204 (or monitor circuitry). The monitored voltages can be at least one of, preferably all, voltages of each elementary component of buffer 204 (e.g., of C_{EB}, C_{EB1}, C_{EB2}, L_{EB1}, L_{EB2}, DEB) independent of the other components, or the voltages of groups of elementary components or buffer 204 as a whole (e.g., between IO1 and IO2 or between IO3 and IO4). Similarly the monitored temperatures and currents can be at least one of, preferably all, temperatures and currents of each elementary component of buffer 204 independent of the other components, or the temperatures and currents of groups of elementary components or of buffer 204 as a whole, or any combination thereof. The monitored signals can be status information, with which LCD 114 can perform one or more of the following: set or output a warning or alarm indication; communicate the status information to MCD 112; or control converter 202 to adjust (increase or decrease) the utilization of source 206 and module 108 as a whole for buffer protection.

To control and protect converter 202, LCD 114 can receive the control information from MCD 112 (e.g., a modulated reference signal, or a reference signal and a modulation index), which can be used with a PWM technique in LCD 114 to generate the control signals for each switch (e.g., S1 through S6). LCD 114 can receive a current feedback signal from a current sensor of converter 202, which can be used for overcurrent protection together with one or more fault status signals from driver circuits (not shown) of the converter switches, which can carry information about fault statuses (e.g., short circuit or open circuit failure modes) of all switches of converter 202. Based on this data, LCD 114 can make a decision on which combination of switching signals to be applied to manage utilization of module 108, and potentially bypass or disconnect converter 202 (and the entire module 108) from system 100.

If controlling a module 108C that supplies a second auxiliary load 302, LCD 114 can receive one or more monitored voltages (e.g., the voltage between IO ports 5 and 6) and one or more monitored currents (e.g., the current in coupling inductor Lc, which is a current of load 302) in module 108C. Based on these signals, LCD 114 can adjust the switching cycles (e.g., by adjustment of modulation index or reference waveform) of S1 and S2 to control (and stabilize) the voltage for load 302.

### Cascaded Energy System Topology Examples

Two or more modules 108 can be coupled together in a cascaded array that outputs a voltage signal formed by a superposition of the discrete voltages generated by each module 108 within the array. FIG. 7A is a block diagram depicting an example embodiment of a topology for system 100 where N modules 108-1, 108-2 . . . 108-N are coupled together in series to form a serial array 700. In this and all embodiments described herein, N can be any integer greater than one. Array 700 includes a first system IO port SIO1 and a second system IO port SIO2 across which is generated an array output voltage. Array 700 can be used as a DC or single phase AC energy source for DC or AC single-phase loads, which can be connected to SIO1 and SIO2 of array 700. FIG. 8A is a plot of voltage versus time depicting an example output signal produced by a single module 108 having a 48 volt energy source. FIG. 8B is a plot of voltage versus time depicting an example single phase AC output signal generated by array 700 having six 48V modules 108 coupled in series.

System 100 can be arranged in a broad variety of different topologies to meet varying needs of the applications. System 100 can provide multi-phase power (e.g., two-phase, three-phase, four-phase, five-phase, six-phase, etc.) to a load by use of multiple arrays 700, where each array can generate an AC output signal having a different phase angle.

FIG. 7B is a block diagram depicting system 100 with two arrays 700-PA and 700-PB coupled together. Each array 700 is one-dimensional, formed by a series connection of N modules 108. The two arrays 700-PA and 700-PB can each generate a single-phase AC signal, where the two AC signals have different phase angles PA and PB (e.g., 180 degrees apart). IO port 1 of module 108-1 of each array 700-PA and 700-PB can form or be connected to system IO ports SIO1 and SIO2, respectively, which in turn can serve as a first output of each array that can provide two phase power to a load (not shown). Or alternatively ports SIO1 and SIO2 can be connected to provide single phase power from two parallel arrays. IO port 2 of module 108-N of each array 700-PA and 700-PB can serve as a second output for each array 700-PA and 700-PB on the opposite end of the array from system IO ports SIO1 and SIO2, and can be coupled together at a common node and optionally used for an additional system IO port SIO3 if desired, which can serve as a neutral. This common node can be referred to as a rail, and IO port 2 of modules 108-N of each array 700 can be referred to as being on the rail side of the arrays.

FIG. 7C is a block diagram depicting system 100 with three arrays 700-PA, 700-PB, and 700-PC coupled together. Each array 700 is one-dimensional, formed by a series connection of N modules 108. The three arrays 700-1 and 700-2 can each generate a single-phase AC signal, where the three AC signals have different phase angles PA, PB, PC (e.g., 120 degrees apart). IO port 1 of module 108-1 of each array 700-PA, 700-PB, and 700-PC can form or be connected to system IO ports SIO1, SIO2, and SIO3, respectively, which in turn can provide three phase power to a load (not shown). IO port 2 of module 108-N of each array 700-PA, 700-PB, and 700-PC can be coupled together at a common node and optionally used for an additional system IO port SIO4 if desired, which can serve as a neutral.

The concepts described with respect to the two-phase and three-phase embodiments of FIGS. 7B and 7C can be extended to systems 100 generating still more phases of power. For example, a non-exhaustive list of additional examples includes: system 100 having four arrays 700, each of which is configured to generate a single phase AC signal having a different phase angle (e.g., 90 degrees apart): system 100 having five arrays 700, each of which is configured to generate a single phase AC signal having a different phase angle (e.g., 72 degrees apart); and system 100 having six arrays 700, each array configured to generate a single phase AC signal having a different phase angle (e.g., 60 degrees apart).

System 100 can be configured such that arrays 700 are interconnected at electrical nodes between modules 108 within each array. FIG. 7D is a block diagram depicting system 100 with three arrays 700-PA, 700-PB, and 700-PC coupled together in a combined series and delta arrangement. Each array 700 includes a first series connection of M modules 108, where M is two or greater, coupled with a second series connection of N modules 108, where N is two or greater. The delta configuration is formed by the interconnections between arrays, which can be placed in any desired location. In this embodiment, IO port 2 of module 108-(M+N) of array 700-PC is coupled with IO port 2 of module 108-M and IO port 1 of module 108-(M+1) of array 700-PA, IO port 2 of module 108-(M+N) of array 700-PB is coupled with IO port 2 of module 108-M and IO port 1 of module 108-(M+1) of array 700-PC, and IO port 2 of module 108-(M+N) of array 700-PA is coupled with IO port 2 of module 108-M and IO port 1 of module 108-(M+1) of array 700-PB.

FIG. 7E is a block diagram depicting system 100 with three arrays 700-PA, 700-PB, and 700-PC coupled together in a combined series and delta arrangement. This embodiment is similar to that of FIG. 7D except with different cross connections. In this embodiment, IO port 2 of module 108-M of array 700-PC is coupled with IO port 1 of module 108-1 of array 700-PA, IO port 2 of module 108-M of array 700-PB is coupled with IO port 1 of module 108-1 of array 700-PC, and IO port 2 of module 108-M of array 700-PA is coupled with IO port 1 of module 108-1 of array 700-PB. The arrangements of FIGS. 7D and 7E can be implemented with as little as two modules in each array 700. Combined delta and series configurations enable an effective exchange of energy between all modules 108 of the system (interphase balancing) and phases of power grid or load, and also allows reducing the total number of modules 108 in an array 700 to obtain the desired output voltages.

In the embodiments described herein, although it is advantageous for the number of modules 108 to be the same in each array 700 within system 100, such is not required and different arrays 700 can have differing numbers of modules 108. Further, each array 700 can have modules 108 that are all of the same configuration (e.g., all modules are 108A, all modules are 108B, all modules are 108C, or others) or different configurations (e.g., one or more modules are 108A, one or more are 108B, and one or more are 108C, or otherwise). As such, the scope of topologies of system 100 covered herein is broad.

### Control Methodology Examples

As mentioned, control of system 100 can be performed according to various methodologies, such as hysteresis or PWM. Several examples of PWM include space vector modulation and sine pulse width modulation, where the switching signals for converter 202 are generated with a phase shifted carrier technique that continuously rotates utilization of each module 108 to equally distribute power among them.

FIGS. 8C-8F are plots depicting an example embodiment of a phase-shifted PWM control methodology that can generate a multilevel output PWM waveform using incrementally shifted two-level waveforms. An X-level PWM waveform can be created by the summation of (X-1)/2 two-level PWM waveforms. These two-level waveforms can be generated by comparing a reference waveform Vref to carriers incrementally shifted by 360°/(X-1). The carriers are triangular, but the embodiments are not limited to such. A nine-level example is shown in FIG. 8C (using four modules 108). The carriers are incrementally shifted by 360°/(9-1)=45° and compared to Vref. The resulting two-level PWM waveforms are shown in FIG. 8E. These two-level waveforms may be used as the switching signals for semiconductor switches (e.g., S1 though S6) of converters 202. As an example with reference to FIG. 8E, for a one-dimensional array 700 including four modules 108 each with a converter 202, the 0° signal is for control of S3 and the 180° signal for S6 of the first module 108-1, the 45° signal is for S3 and the 225° signal for S6 of the second module 108-2, the 90 signal is for S3 and the 270 signal is for S6 of the third module 108-3, and the 135 signal is for S3 and the 315 signal is for S6 of the fourth module 108-4. The signal for S3 is complementary to S4 and the signal for S5 is complementary to S6 with sufficient dead-time to avoid shoot through of each half-bridge. FIG. 8F depicts an example single phase AC waveform produced by superposition (summation) of output voltages from the four modules 108.

An alternative is to utilize both a positive and a negative reference signal with the first (N−1)/2 carriers. A nine-level example is shown in FIG. 8D. In this example, the 0° to 135° switching signals (FIG. 8E) are generated by comparing+Vref to the 0° to 135° carriers of FIG. 8D and the 180° to 315° switching signals are generated by comparing-Vref to the 0° to 135° carriers of FIG. 8D. However, the logic of the comparison in the latter case is reversed. Other techniques such as a state machine decoder may also be used to generate gate signals for the switches of converter 202.

In multi-phase system embodiments, the same carriers can be used for each phase, or the set of carriers can be shifted as a whole for each phase. For example, in a three phase system with a single reference voltage (Vref), each array 700 can use the same number of carriers with the same relative offsets as shown in FIGS. 8C and 8D, but the carriers of the second phase are shift by 120 degrees as compared to the carriers of the first phase, and the carriers of the third phase are shifted by 240 degrees as compared to the carriers of the first phase. If a different reference voltage is available for each phase, then the phase information can be carried in the reference voltage and the same carriers can be used for each phase. In many cases the carrier frequencies will be fixed, but in some example embodiments, the carrier frequencies can be adjusted, which can help to reduce losses in EV motors under high current conditions.

The appropriate switching signals can be provided to each module by control system 102. For example, MCD 112 can provide Vref and the appropriate carrier signals to each LCD 114 depending upon the module or modules 108 that LCD 114 controls, and the LCD 114 can then generate the switching signals. Or all LCDs 114 in an array can be provided with all carrier signals and the LCD can select the appropriate carrier signals.

The relative utilizations of each module 108 can adjusted based on status information to perform balancing or of one or more parameters as described herein. Balancing of parameters can involve adjusting utilization to minimize parameter divergence over time as compared to a system where individual module utilization adjustment is not performed. The utilization can be the relative amount of time a module 108 is discharging when system 100 is in a discharge state, or the relative amount of time a module 108 is charging when system 100 is in a charge state.

As described herein, modules 108 can be balanced with respect to other modules in an array 700, which can be referred to as intra array or intraphase balancing, and different arrays 700 can be balanced with respect to each other, which can be referred to as interarray or interphase balancing. Arrays 700 of different subsystems can also be balanced with respect to each other. Control system 102 can simultaneously perform any combination of intraphase balancing, interphase balancing, utilization of multiple energy sources within a module, active filtering, and auxiliary load supply.

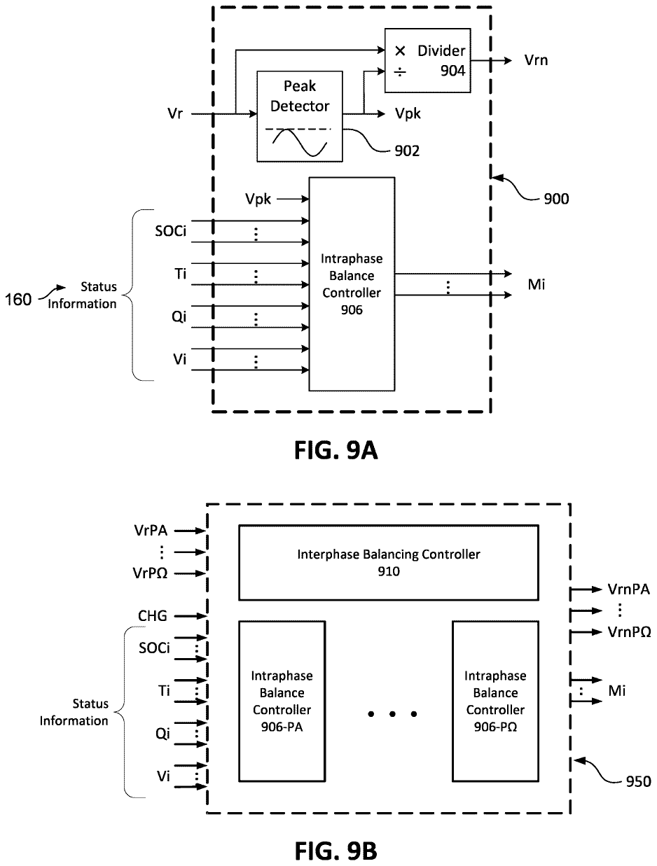

FIG. 9A is a block diagram depicting an example embodiment of an array controller 900 of control system 102 for a single-phase AC or DC array. Array controller 900 can include a peak detector 902, a divider 904, and an intraphase (or intra array) balance controller 906. Array controller 900 can receive a reference voltage waveform (Vr) and status information about each of the N modules 108 in the array (e.g., state of charge (SOCi), temperature (Ti), capacity (Qi), and voltage (Vi)) as inputs, and generate a normalized reference voltage waveform (Vrn) and modulation indexes (Mi) as outputs. Peak detector 902 detects the peak (Vpk) of Vr, which can be specific to the phase that controller 900 is operating with and/or balancing. Divider 904 generates Vrn by dividing Vr by its detected Vpk. Intraphase balance controller 906 uses Vpk along with the status information (e.g., SOCi, Ti, Qi, Vi, etc.) to generate modulation indexes Mi for each module 108 within the array 700 being controlled.

The modulation indexes and Vrn can be used to generate the switching signals for each converter 202. The modulation index can be a number between zero and one (inclusive of zero and one). For a particular module 108, the normalized reference Vrn can be modulated or scaled by Mi, and this modulated reference signal (Vrnm) can be used as Vref (or −Vref) according to the PWM technique described with respect to FIGS. 8C-8F, or according to other techniques. In this manner, the modulation index can be used to control the PWM switching signals provided to the converter switching circuitry (e.g., S3-S6 or S1-S6), and thus regulate the operation of each module 108. For example, a module 108 being controlled to maintain normal or full operation may receive an Mi of one, while a module 108 being controlled to less than normal or full operation may receive an Mi less than one, and a module 108 controlled to cease power output may receive an Mi of zero. This operation can be performed in various ways by control system 102, such as by MCD 112 outputting Vrn and Mi to the appropriate LCDs 114 for modulation and switch signal generation, by MCD 112 performing modulation and outputting the modulated Vrnm to the appropriate LCDs 114 for switch signal generation, or by MCD 112 performing modulation and switch signal generation and outputting the switch signals to the LCDs or the converters 202 of each module 108 directly. Vrn can be sent continually with Mi sent at regular intervals, such as once for every period of the Vrn, or one per minute, etc.

Controller 906 can generate an Mi for each module 108 using any type or combination of types of status information (e.g., SOC, temperature (T), Q, SOH, voltage, current) described herein. For example, when using SOC and T, a module 108 can have a relatively high Mi if SOC is relatively high and temperature is relatively low as compared to other modules 108 in array 700. If either SOC is relatively low or T is relatively high, then that module 108 can have a relatively low Mi, resulting in less utilization than other modules 108 in array 700. Controller 906 can determine Mi such that the sum of module voltages does not exceed Vpk. For example, Vpk can be the sum of the products of the voltage of each module's source 206 and Mi for that module (e.g., Vpk=M₁V₁+M₂V₂+M₃V₃ . . . +M_{N}V_{N}, etc). A different combination of modulation indexes, and thus respective voltage contributions by the modules, may be used but the total generated voltage should remain the same.

Controller 900 can control operation, to the extent it does not prevent achieving the power output requirements of the system at any one time (e.g., such as during maximum acceleration of an EV), such that SOC of the energy source(s) in each module 108 remains balanced or converges to a balanced condition if they are unbalanced, and/or such that temperature of the energy source(s) or other component (e.g., energy buffer) in each module remains balanced or converges to a balanced condition if they are unbalanced. Power flow in and out of the modules can be regulated such that a capacity difference between sources does not cause an SOC deviation. Balancing of SOC and temperature can indirectly cause some balancing of SOH. Voltage and current can be directly balanced if desired, but in many embodiments the main goal of the system is to balance SOC and temperature, and balancing of SOC can lead to balance of voltage and current in a highly symmetric systems where modules are of similar capacity and impedance.

Since balancing all parameters may not be possible at the same time (e.g., balancing of one parameter may further unbalance another parameter), a combination of balancing any two or more parameters (SOC, T, Q, SOH, V, I) may be applied with priority given to either one depending on the requirements of the application. Priority in balancing can be given to SOC over other parameters (T, Q, SOH, V, I), with exceptions made if one of the other parameters (T, Q, SOH, V, I) reaches a severe unbalanced condition outside a threshold.

Balancing between arrays 700 of different phases (or arrays of the same phase, e.g., if parallel arrays are used) can be performed concurrently with intraphase balancing. FIG. 9B depicts an example embodiment of an Ω-phase (or (Ω-array) controller 950 configured for operation in an Ω-phase system 100, having at least Ω arrays 700, where 22 is any integer greater than one. Controller 950 can include one interphase (or interarray) controller 910 and Ω intraphase balance controllers 906-PA . . . 906-PΩ for phases PA through PΩ, as well as peak detector 902 and divider 904 (FIG. 9A) for generating normalized references VrnPA through VrnPΩ from each phase-specific reference VrPA through VrPΩ. Intraphase controllers 906 can generate Mi for each module 108 of each array 700 as described with respect to FIG. 9A. Interphase balance controller 910 is configured or programmed to balance aspects of modules 108 across the entire multi-dimensional system, for example, between arrays of different phases. This may be achieved through injecting common mode to the phases (e.g., neutral point shifting) or through the use of interconnection modules (described herein) or through both. Common mode injection involves introducing a phase and amplitude shift to the reference signals VrPA through VrPΩ to generate normalized waveforms VrnPA through VrnPΩ to compensate for unbalance in one or more arrays, and is described further in Int'l. Appl. No. PCT/US20/25366 incorporated herein.

Controllers 900 and 950 (as well as balance controllers 906 and 910) can be implemented in hardware, software or a combination thereof within control system 102. Controllers 900 and 950 can be implemented within MCD 112, distributed partially or fully among LCDs 114, or may be implemented as discrete controllers independent of MCD 112 and LCDs 114.

### Interconnection (IC) Module Examples

Modules 108 can be connected between the modules of different arrays 700 for the purposes of exchanging energy between the arrays, acting as a source for an auxiliary load, or both. Such modules are referred to herein as interconnection (IC) modules 108IC. IC module 108IC can be implemented in any of the already described module configurations (108A, 108B, 108C) and others to be described herein. IC modules 108IC can include any number of one or more energy sources, an optional energy buffer, switch circuitry for supplying energy to one or more arrays and/or for supplying power to one or more auxiliary loads, control circuitry (e.g., a local control device), and monitor circuitry for collecting status information about the IC module itself or its various loads (e.g., SOC of an energy source, temperature of an energy source or energy buffer, capacity of an energy source, SOH of an energy source, voltage and/or current measurements pertaining to the IC module, voltage and/or current measurements pertaining to the auxiliary load(s), etc.).

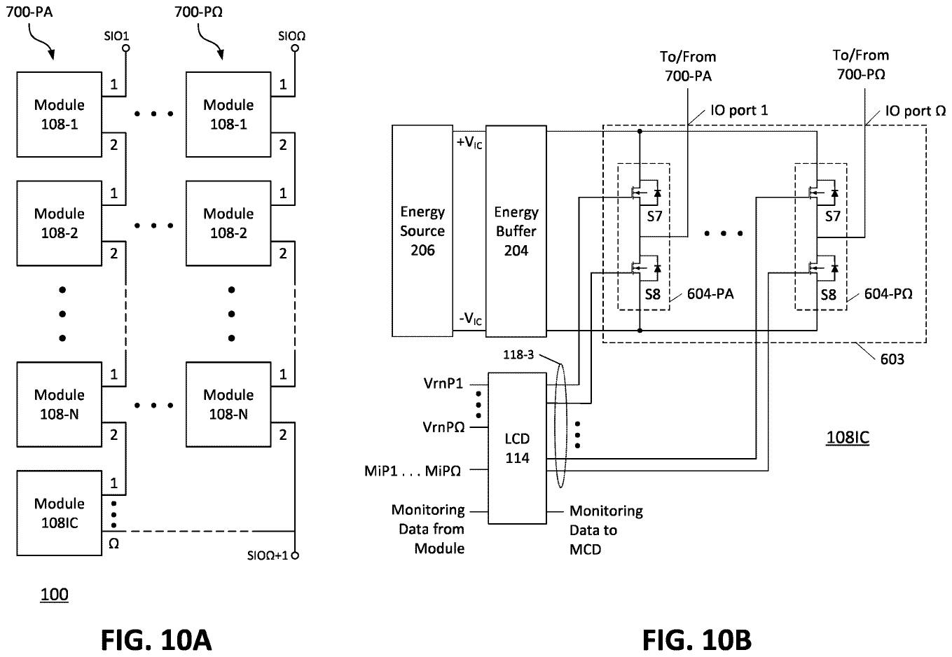

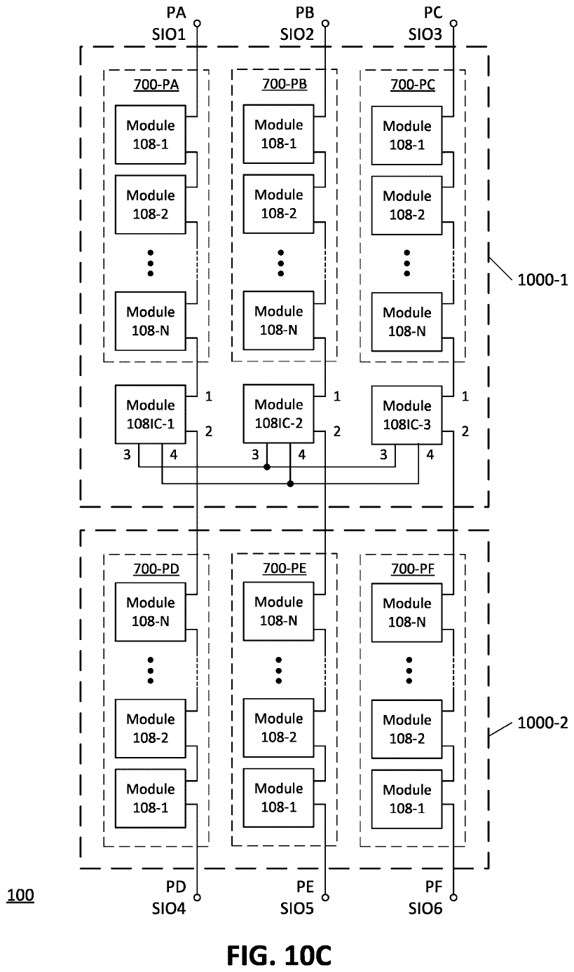

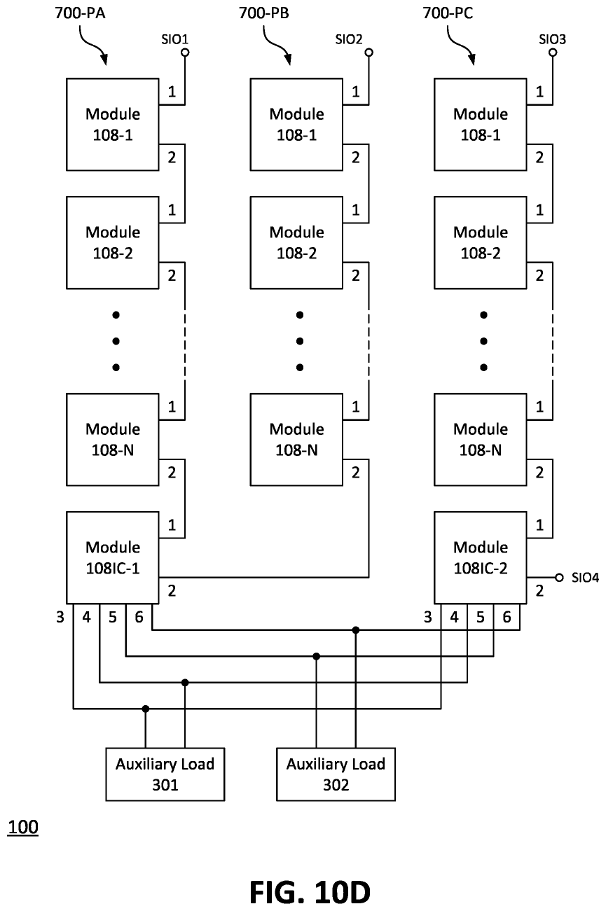

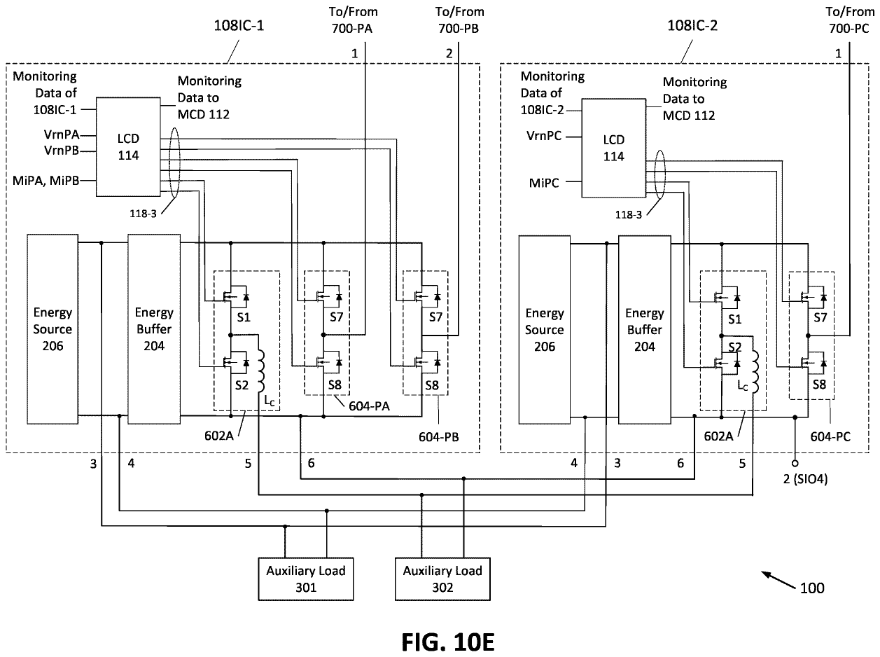

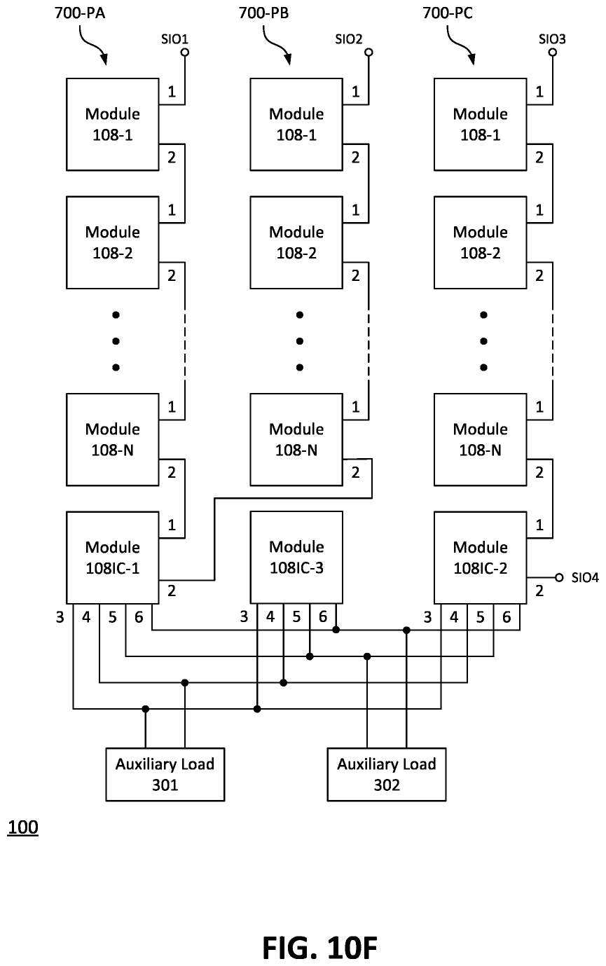

FIG. 10A is a block diagram depicting an example embodiment of a system 100 capable of producing Ω-phase power with Ω arrays 700-PA through 700-PΩ, where Ω can be any integer greater than one. In this and other embodiments, IC module 108IC can be located on the rail side of arrays 700 such the arrays 700 to which module 108IC are connected (arrays 700-PA through 700-PΩ in this embodiment) are electrically connected between module 108IC and outputs (e.g., SIO1 through SIOΩ) to the load. Here, module 108IC has Ω IO ports for connection to IO port 2 of each module 108-N of arrays 700-PA through 700-PΩ. In the configuration depicted here, module 108IC can perform interphase balancing by selectively connecting the one or more energy sources of module 108IC to one or more of the arrays 700-PA through 700-PΩ (or to no output, or equally to all outputs, if interphase balancing is not required). System 100 can be controlled by control system 102 (not shown, see FIG. 1A).

FIG. 10B is a schematic diagram depicting an example embodiment of module 108IC. In this embodiment module 108IC includes an energy source 206 connected with energy buffer 204 that in turn is connected with switch circuitry 603. Switch circuitry 603 can include switch circuitry units 604-PA through 604-PΩ for independently connecting energy source 206 to each of arrays 700-PA through 700-PΩ, respectively. Various switch configurations can be used for each unit 604, which in this embodiment is configured as a half-bridge with two semiconductor switches S7 and S8. Each half bridge is controlled by control lines 118-3 from LCD 114. This configuration is similar to module 108A described with respect to FIG. 3A. As described with respect to converter 202, switch circuitry 603 can be configured in any arrangement and with any switch types (e.g., MOSFET, IGBT, Silicon, GaN, etc.) suitable for the requirements of the application.

Switch circuitry units 604 are coupled between positive and negative terminals of energy source 206 and have an output that is connected to an IO port of module 108IC. Units 604-PA through 604-PQ can be controlled by control system 102 to selectively couple voltage +V_{IC} or −V_{IC} to the respective module I/O ports 1 through Ω. Control system 102 can control switch circuitry 603 according to any desired control technique, including the PWM and hysteresis techniques mentioned herein. Here, control circuitry 102 is implemented as LCD 114 and MCD 112 (not shown). LCD 114 can receive monitoring data or status information from monitor circuitry of module 108IC. This monitoring data and/or other status information derived from this monitoring data can be output to MCD 112 for use in system control as described herein. LCD 114 can also receive timing information (not shown) for purposes of synchronization of modules 108 of the system 100 and one or more carrier signals (not shown), such as the sawtooth signals used in PWM (FIGS. 8C-8D).

For interphase balancing, proportionally more energy from source 206 can be supplied to any one or more of arrays 700-PA through 700-PΩ that is relatively low on charge as compared to other arrays 700. Supply of this supplemental energy to a particular array 700 allows the energy output of those cascaded modules 108-1 thru 108-N in that array 700 to be reduced relative to the unsupplied phase array(s).

For example, in some example embodiments applying PWM, LCD 114 can be configured to receive the normalized voltage reference signal (Vrn) (from MCD 112) for each of the one or more arrays 700 that module 108IC is coupled to, e.g., VrnPA through VrnPΩ. LCD 114 can also receive modulation indexes MiPA through MiPΩ for the switch units 604-PA through 604-PΩ for each array 700, respectively, from MCD 112. LCD 114 can modulate (e.g., multiply) each respective Vrn with the modulation index for the switch section coupled directly to that array (e.g., VrnA multiplied by MiA) and then utilize a carrier signal to generate the control signal(s) for each switch unit 604. In other embodiments, MCD 112 can perform the modulation and output modulated voltage reference waveforms for each unit 604 directly to LCD 114 of module 108IC. In still other embodiments, all processing and modulation can occur by a single control entity that can output the control signals directly to each unit 604.

This switching can be modulated such that power from energy source 206 is supplied to the array(s) 700 at appropriate intervals and durations. Such methodology can be implemented in various ways.

Based on the collected status information for system 100, such as the present capacity (Q) and SOC of each energy source in each array, MCD 112 can determine an aggregate charge for each array 700 (e.g., aggregate charge for an array can be determined as the sum of capacity times SOC for each module of that array). MCD 112 can determine whether a balanced or unbalanced condition exists (e.g., through the use of relative difference thresholds and other metrics described herein) and generate modulation indexes MiPA through MiPΩ accordingly for each switch unit 604-PA through 604-PΩ.

During balanced operation, Mi for each switch unit 604 can be set at a value that causes the same or similar amount of net energy over time to be supplied by energy source 206 and/or energy buffer 204 to each array 700. For example, Mi for each switch unit 604 could be the same or similar, and can be set at a level or value that causes the module 108IC to perform a net or time average discharge of energy to the one or more arrays 700-PA through 700-PΩ during balanced operation, so as to drain module 108IC at the same rate as other modules 108 in system 100. In some embodiments, Mi for each unit 604 can be set at a level or value that does not cause a net or time average discharge of energy during balanced operation (causes a net energy discharge of zero). This can be useful if module 108IC has a lower aggregate charge than other modules in the system.

When an unbalanced condition occurs between arrays 700, then the modulation indexes of system 100 can be adjusted to cause convergence towards a balanced condition or to minimize further divergence. For example, control system 102 can cause module 108IC to discharge more to the array 700 with low charge than the others, and can also cause modules 108-1 through 108-N of that low array 700 to discharge relatively less (e.g., on a time average basis). The relative net energy contributed by module 108IC increases as compared to the modules 108-1 through 108-N of the array 700 being assisted, and also as compared to the amount of net energy module 108IC contributes to the other arrays. This can be accomplished by increasing Mi for the switch unit 604 supplying that low array 700, and by decreasing the modulation indexes of modules 108-1 through 108-N of the low array 700 in a manner that maintains Vout for that low array at the appropriate or required levels, and maintaining the modulation indexes for other switch units 604 supplying the other higher arrays relatively unchanged (or decreasing them).

The configuration of module 108IC in FIGS. 10A-10B can be used alone to provide interphase or interarray balancing for a single system, or can be used in combination with one or more other modules 108IC each having an energy source and one or more switch portions 604 coupled to one or more arrays. For example, a module 108IC with Ω switch portions 604 coupled with Ω different arrays 700 can be combined with a second module 108IC having one switch portion 604 coupled with one array 700 such that the two modules combine to service a system 100 having Ω+1 arrays 700. Any number of modules 108IC can be combined in this fashion, each coupled with one or more arrays 700 of system 100.

Furthermore, IC modules can be configured to exchange energy between two or more subsystems of system 100. FIG. 10C is a block diagram depicting an example embodiment of system 100 with a first subsystem 1000-1 and a second subsystem 1000-2 interconnected by IC modules. Specifically, subsystem 1000-1 is configured to supply three-phase power, PA, PB, and PC, to a first load (not shown) by way of system I/O ports SIO1, SIO2, and SIO3, while subsystem 1000-2 is configured to supply three-phase power PD, PE, and PF to a second load (not shown) by way of system I/O ports SIO4, SIO5, and SIO06, respectively. For example, subsystems 1000-1 and 1000-2 can be configured as different packs supplying power for different motors of an EV or as different racks supplying power for different microgrids.

In this embodiment each module 108IC is coupled with a first array of subsystem 1000-1 (via IO port 1) and a first array of subsystem 1000-2 (via IO port 2), and each module 108IC can be electrically connected with each other module 108IC by way of I/O ports 3 and 4, which are coupled with the energy source 206 of each module 108IC as described with respect to module 108C of FIG. 3C. This connection places sources 206 of modules 108IC-1, 108IC-2, and 108IC-3 in parallel, and thus the energy stored and supplied by modules 108IC is pooled together by this parallel arrangement. Other arrangements such as serious connections can also be used. Modules 108IC are housed within a common enclosure of subsystem 1000-1, however the interconnection modules can be external to the common enclosure and physically located as independent entities between the common enclosures of both subsystems 1000.

Each module 108IC has a switch unit 604-1 coupled with IO port 1 and a switch unit 604-2 coupled with I/O port 2, as described with respect to FIG. 10B. Thus, for balancing between subsystems 1000 (e.g., inter-pack or inter-rack balancing), a particular module 108IC can supply relatively more energy to either or both of the two arrays to which it is connected (e.g., module 108IC-1 can supply to array 700-PA and/or array 700-PD). The control circuitry can monitor relative parameters (e.g., SOC and temperature) of the arrays of the different subsystems and adjust the energy output of the IC modules to compensate for imbalances between arrays or phases of different subsystems in the same manner described herein as compensating for imbalances between two arrays of the same rack or pack. Because all three modules 108IC are in parallel, energy can be efficiently exchanged between any and all arrays of system 100. In this embodiment, each module 108IC supplies two arrays 700, but other configurations can be used including a single IC module for all arrays of system 100 and a configuration with one dedicated IC module for each array 700 (e.g., six IC modules for six arrays, where each IC module has one switch unit 604). In all cases with multiple IC modules, the energy sources can be coupled together in parallel so as to share energy as described herein.

In systems with IC modules between phases, interphase balancing can also be performed by neutral point shifting (or common mode injection) as described above. Such a combination allows for more robust and flexible balancing under a wider range of operating conditions. System 100 can determine the appropriate circumstances under which to perform interphase balancing with neutral point shifting alone, interphase energy injection alone, or a combination of both simultaneously.

IC modules can also be configured to supply power to one or more auxiliary loads 301 (at the same voltage as source 206) and/or one or more auxiliary loads 302 (at voltages stepped down from source 302). FIG. 10D is a block diagram depicting an example embodiment of a three-phase system 100 A with two modules 108IC connected to perform interphase balancing and to supply auxiliary loads 301 and 302. FIG. 10E is a schematic diagram depicting this example embodiment of system 100 with emphasis on modules 108IC-1 and 108IC-2. Here, control circuitry 102 is again implemented as LCD 114 and MCD 112 (not shown). The LCDs 114 can receive monitoring data from modules 108IC (e.g., SOC of ES1, temperature of ES1, Q of ES1, voltage of auxiliary loads 301 and 302, etc.) and can output this and/or other monitoring data to MCD 112 for use in system control as described herein. Each module 108IC can include a switch portion 602A (or 602B described with respect to FIG. 6C) for each load 302 being supplied by that module, and each switch portion 602 can be controlled to maintain the requisite voltage level for load 302 by LCD 114 either independently or based on control input from MCD 112. In this embodiment, each module 108IC includes a switch portion 602A connected together to supply the one load 302, although such is not required.

FIG. 10F is a block diagram depicting another example embodiment of a three-phase system configured to supply power to one or more auxiliary loads 301 and 302 with modules 108IC-1, 108IC-2, and 108IC-3. In this embodiment, modules 108IC-1 and 108IC-2 are configured in the same manner as described with respect to FIGS. 10D-10E. Module 108IC-3 is configured in a purely auxiliary role and does not actively inject voltage or current into any array 700 of system 100. In this embodiment, module 108IC-3 can be configured like module 108C of FIG. 3B, having a converter 202B,C (FIGS. 6B-6C) with one or more auxiliary switch portions 602A, but omitting switch portion 601. As such, the one or more energy sources 206 of module 108IC-3 are interconnected in parallel with those of modules 108IC-1 and 108IC-2, and thus this embodiment of system 100 is configured with additional energy for supplying auxiliary loads 301 and 302, and for maintaining charge on the sources 206A of modules 108IC-1 and 108IC-2 through the parallel connection with the source 206 of module 108IC-3.

The energy source 206 of each IC module can be at the same voltage and capacity as the sources 206 of the other modules 108-1 through 108-N of the system, although such is not required. For example, a relatively higher capacity can be desirable in an embodiment where one module 108IC applies energy to multiple arrays 700 (FIG. 10A) to allow the IC module to discharge at the same rate as the modules of the phase arrays themselves. If the module 108IC is also supplying an auxiliary load, then an even greater capacity may be desired so as to permit the IC module to both supply the auxiliary load and discharge at relatively the same rate as the other modules.

### Online Impedance Measurement Examples Using Perturbation

All of the embodiments of system 100 described herein can include integrated impedance measurement technology as described below, which leverages components of module 108 to perform impedance measurements of energy source 206 in a rapid and flexible manner. For example, rather than adding dedicated EIS hardware to generate perturbation signals for impedance measurement along with additional voltage and current sensors, control techniques used to control switching of a converter can be adjusted to inject a perturbation current on terminals of energy source 206 for impedance measurement. Voltage and current measurements of converter 202 or a BMS for energy source 206 can be used to determine the impedance of energy source 206 such that additional voltage and/or current sensors are not required.

The impedance of energy source 206 can be a useful parameter to measure when determining the status of energy source 206, for future operations, for anticipation of maintenance, and/or for general monitoring of system health and performance degradation over time. For example, where energy source 206 is a battery, an increase in impedance can indicate a degradation of one or more cells within the battery, suggesting battery or cell replacement may be necessary. As described in more detail below, impedance measurements can be logged over time and used to detect the status and/or characteristics of energy sources 206, facilitating determinations such as SOC, SOH, and capacity. For example, the impedance measurements can be used to monitor the status and characteristics of batteries of EVs to predict when the batteries will need replacement.

As many applications for energy sources 206 include a converter (e.g., converter 202) to provide input to or output from energy source 206, converter 202 can also be used to generate perturbation signals for use in impedance measurement. By using hardware of converter 202, which may already be a component of module 108, energy source 206 need not be removed from the system 100, or taken offline for the impedance measurement to occur. Additionally, it is not necessary to make or break any connections that are specific to the impedance measurement. The result is a reduced cost, rapid impedance measurement that can be implemented using hardware that is already included in module 108, e.g., without requiring additional EIS hardware or additional voltage and/or current sensors.

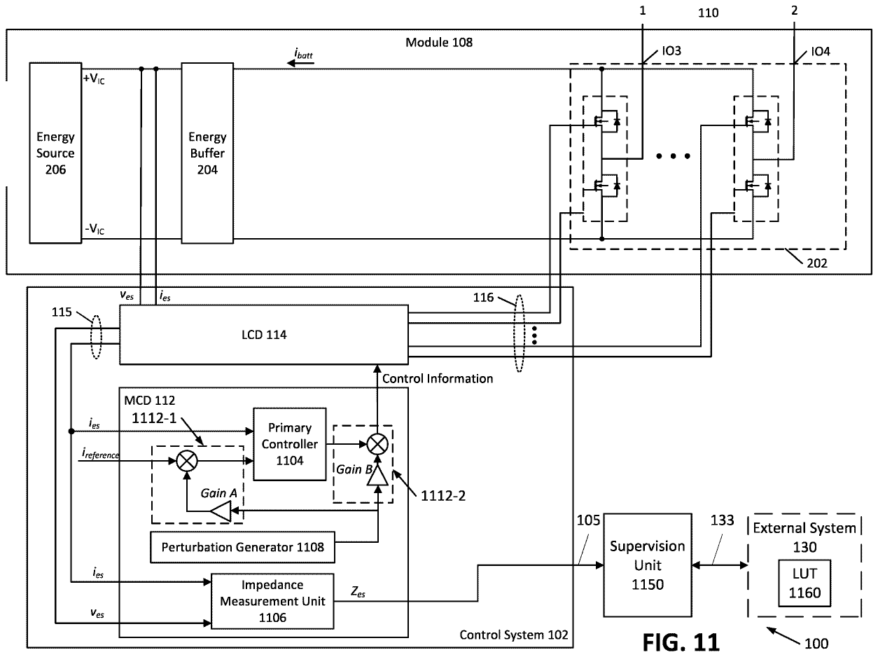

FIG. 11 is a block diagram depicting an example embodiment of an energy system 100 having a control system 102 configured to perform online impedance measurement. Online impedance measurement can refer to impedance measurements that are made while an energy source 206 is in normal operation conditions, e.g., when deployed in a system and directly or indirectly electrically coupled to load. To improve accuracy of the impedance measurements, the impedance measurements can be made when energy source 206 is not being charged or discharged e.g., when the voltage of energy source 206 is steady and the current to or from energy source 206 is low (e.g., less than a threshold). For example, the impedance measurements for an energy source 206 can be made when the charge or discharge current of an energy source 206 is less than a specified threshold, as described below. In an electric vehicle embodiment, this current can be less than the threshold when the electric vehicle is idle, e.g., when the accelerator is in an idle position and regenerative braking and other types of charging for the energy source 206 are not occurring. Thus, the impedance measurements for an energy source 206 can be made while electrically coupled to system 100 and its loads, but while the charge and discharge current of energy source is less than a threshold.

In some situations, some energy sources 206 may be charging or discharging while other sources are not. For example, a first energy source 206 may be providing power to an auxiliary load while a second energy source 206 is not currently charging or discharging. In such situations, impedance measurements can be made for the first energy source 206 and impedance measurements can be made for the second energy source 206 at another time, e.g., when the charging or discharging current for the second energy source 206 is less than the threshold. In another example, energy sources 206 of a first array 700 of modules 108 may be charging, while energy sources 206 of a second array 700 are not being charged. In this example, impedance measurements can be made for the energy sources 206 of the second array 700 and impedance measurements can be made for the energy sources of the first array 700 at another time, e.g., when charging is complete or there is a break in charging such that the charging current is less than the threshold.

System 100, including modules 108 and control system 102, can be configured in accordance with any and all embodiments described herein. In this embodiment, control system 102 includes an MCD 112 and LCD 114. Under the direction of MCD 112, LCD 114 controls switch circuitry of converter 202 that can both supply current to energy source 206 from IO ports IO3 and IO4 (e.g., connected to module ports 1 and 2 for power connection 110), and withdraw current from energy source 206 to supply the IO ports, e.g., for providing electrical energy to load 101. Switches of converter 202 are activated or deactivated using control signals provided by LCD 114.

MCD 112 includes a primary controller 1104 that generates the control information provided to LCD 114. Primary controller 1104 can be a closed loop system, which receives a sensed current (iₑₛ) and/or other parameters and a target current (i_{reference}) and generates the control information for module 108 (and any other modules controlled by MCD 112) using a control algorithm. Suitable control algorithms can include, for example, classic control algorithms such as a proportional controller, proportional-integral (PI) controller, proportional-derivative (PD) controller, or proportional-integral-derivative (PID) controller. Additional control algorithms can be modern control algorithms, such as a linear-quadratic regulator (LQR) or a linear-quadratic Gaussian (LQG) controller, fuzzy logic, robust control, adaptive controller, stochastic control, non-linear control, or other appropriate algorithm. Primary controller 1104 can be implemented using controller 900 or 950 of FIGS. 9A-9B or any other controller described herein.

Impedance measurement unit 1106 measures the impedance of energy source 206 when a perturbation signal (e.g., perturbation voltage and/or current) is introduced to the energy source 206. Impedance measurement unit 1106 can record current measurements and voltage measurements of energy source 206 and determine an impedance of energy source 206 based on the current and voltage measurements. In some embodiments, impedance measurement unit 1106 or LCD 114 includes, or is electrically coupled to, a shunt resistor (not shown) electronically placed across the output terminals of energy source 206 for measurement. Voltage across and current through the shunt resistor can be measured to determine a gain measurement and a phase measurement across a range of frequencies. In the illustrated embodiment, LCD 114 can measure the voltage and current or receive the voltage measurements Ves and current measurements les from voltage and current sensors electrically coupled to measure the voltage and current of the shunt resistor. LCD 114 can provide the voltage and current measurements to MCD 112 and/or impedance measurement unit 1160 over communication paths or links 115. The current measurement les represents the amount of current into energy source 206 or output by energy source 206. In some embodiments, impedance measurement unit 1106 performs a Fourier Transform or a Fast Fourier Transform (FFT) in order to provide a phase angle and magnitude for impedance across a broad frequency spectrum.

Impedance measurement unit 1160 can be implemented in hardware, software or a combination thereof within MCD 112. Impedance measurement unit 1160 can be implemented within MCD 112, within LCD 114, or may be implemented as a discrete hardware component independent of MCD 112 and LCDs 114. Impedance measurement unit 1160 can include hardware instructions and/or software instructions for performing Fourier Transforms and/or FFTs.

In some embodiments, MCD 112 receives the current and voltage measurements of energy source 206 for use in determining the control information that is provided to module 108. For example, these measurements can be used as feedback by primary controller 1104 to regulate the voltage and/or current output by module 108. As such, the same sensors used for controlling module 108 can be used to determine the impedance measurements. In other words, no additional sensors have to be added to module 108 for the impedance measurements as these sensors are already present for control purposes.

To determine the frequency response of energy source 206 over a broad frequency spectrum, control system 102 causes a perturbation signal (e.g., a perturbation voltage and/or perturbation current) to be provided for energy source 206. Perturbation generator 1108 controls converter 202 to introduce a perturbation signal at energy source 206. In general, perturbation generator 1108 can control converter 202 to introduce the perturbation signal by providing the perturbation reference, which can be a reference voltage or current waveform with components for multiple frequencies. The perturbation reference can have a lower amplitude than the reference signal of the control information generated by primary controller 1104. The perturbation signal can be a wideband signal, or a signal that includes a broad range of frequencies. For example, the frequency range of the perturbation signal can be from in the millihertz (mHz) to in the kilohertz (kHz), e.g., from 10 mHz to 10 kHz or greater or another appropriate frequency range. In some embodiments, the bandwidth of the perturbation signal can be half of the switching frequency of converter 202, which is essentially the converter's natural bandwidth. By injecting current at a broad range of frequencies to energy source 206, impedance measurement unit 1106 can determine the response of energy source 206 for many different frequencies, providing wideband impedance measurements. These measurements can be used to detect different types of energy source degradations, e.g., battery degradations, as described herein.

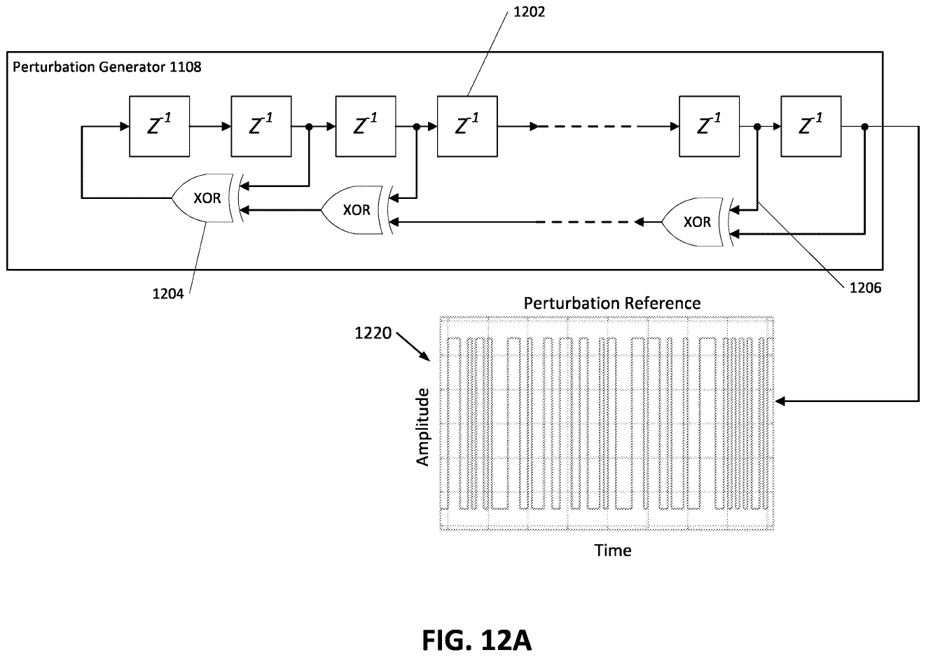

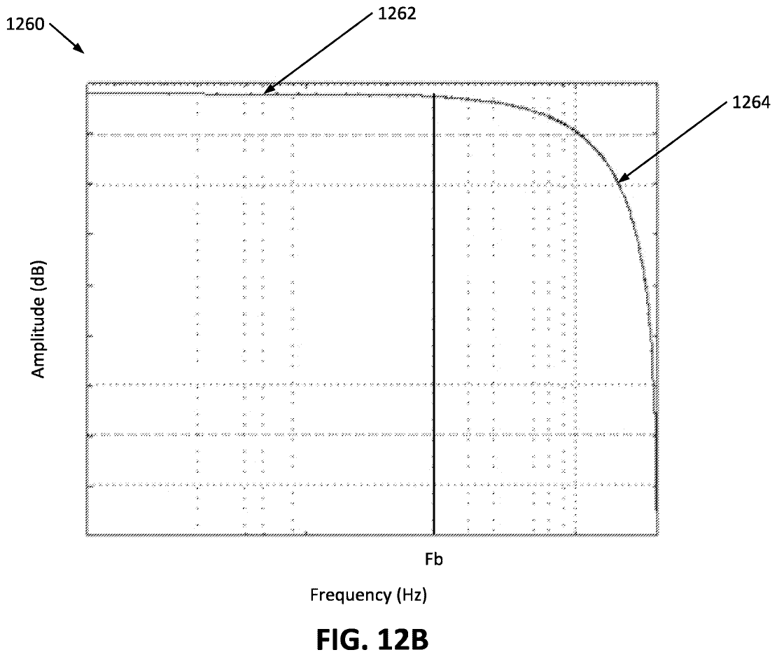

Perturbation generator 1108 can be configured to generate the wideband perturbation reference such that it and the resultant perturbation signal approximates or simulates white noise over the wide bandwidth. The perturbation reference can, for example, be a deterministic, periodic signal such as one based on a pseudo random binary sequence (PRBS). PRBS signals can be readily generated using linear feedback shift-registers and exclusive OR (XOR) logic gates. The generation of PRBS signals is further described below with reference to FIG. 12A. In this example, the perturbation reference is generated and sent to controllers 1104, 114 via two paths for increasing impedance measurement accuracy across the frequency band of interest.

The perturbation reference output by perturbation generator 1108 is adjusted using (e.g., multiplied by) a gain value B (where B is a real number) and combined with the reference signal (which may be a modulated reference signal as described herein) of the control information at the input of LCD 114. A combiner module 1112-2 can apply gain B to the perturbation reference and combine the adjusted perturbation reference with the reference signal of the control information, e.g., by multiplying the reference signal by the adjusted perturbation signal. Combining the perturbation reference with the reference signal can include adding the perturbation reference to the reference signal (or determining a product of the perturbation reference and the reference signal), which can also be referred to as adding the perturbation signal to the duty cycle of the converter 202.

Combining the perturbation reference with the reference signal prior to LCD 114 receiving the reference signal provides high quality impedance measurements at higher frequencies. However, if the perturbation reference is only combined with the reference signal, the impedance measurements at lower frequencies may not be as accurate. One of the reasons for this is that the closed-loop control of control system 102 typically has a large gain within the lower frequency range where control system 102 causes a larger attenuation to the injected perturbation. This is due to the fact that, for high frequency components that are beyond the bandwidth of converter 202, converter 202 is essentially running open loop presenting its natural frequency response, with mild attenuation to the injected perturbation signal. As a result, control system 102 acts as a high pass filter attenuating the lower frequency perturbations, resulting in lower currents at those frequencies than expected and therefore less accurate impedance measurements. In other words, if the wideband perturbation reference is only combined with the reference signal, primary controller 1104 would act as though any detected current at the lower frequencies of this perturbation reference within the bandwidth of primary controller 1104 is noise and adjust the control information to attenuate the current, resulting in the reduced current at energy source 206 and less accurate impedance measurements of energy source 206 at those lower frequencies.

To enable accurate impedance measurements at lower frequencies as well as higher frequencies, a combiner module 1112-1 adjusts the perturbation reference using a real number gain value A (e.g., by multiplying the perturbation reference by gain A) and combines the adjusted perturbation reference with the reference signal input to primary controller 1104, e.g., by multiplying the reference signal by the adjusted perturbation reference. This combination of the perturbation reference with the reference signal input prevents primary controller 1104 from interpreting the perturbation reference as “noise” and allows the lower frequency components of the perturbation reference to pass to energy source 206. In embodiments where primary controller 1104 has a limited bandwidth, the application of the perturbation reference at the output, or along both paths as described with respect to FIG. 11, prevents high frequencies of the perturbation reference from being lost if they are greater than the controller 1104's bandwidth. By injecting the perturbation reference into the current reference (ireference), the part of the wideband perturbation reference that was attenuated before is now passed through within the bandwidth of converter 202. Beyond the bandwidth of converter 202, the perturbation comes from the injection in the duty cycle, e.g., in the reference signal of the control information provided to LCD 114. Thus, combining gain adjusted perturbation references with both the reference signal input to primary controller 1104 and the reference signal of the control information output by primary controller 1104 ensures that the perturbation reference has a flat response over its full bandwidth or at least the bandwidth of interest (as shown in FIG. 12B), thereby ensuring accurate impedance measurements across the entire frequency band of interest. This is important for battery impedance measurement as the low frequency range impedance measurement data provides useful battery state (e.g., SOH) related information

In some embodiments, the perturbation reference may only be applied along one of the paths, either the input side of controller 1104 or the output side. For example, if the frequency band of interest is only high frequencies or only low frequencies, but not both, only one path could be used to obtain accurate impedance measurements at the frequencies of interest.

Impedance measurement unit 1106 can provide, for each impedance measurement Zₑₛ, impedance data that represents the impedance of energy source 206 to supervision unit 1150. As the impedance can include resistive and reactive components, the impedance data can include, for each of multiple frequencies for which impedance was measured, a vector (or the modulus of the vector) that represents the resistive and reactive components of the measured impedance and the phase angle (φ) between the resistive and reactive components. In another example, the impedance data can include, for each of the multiple frequencies, the values for the real and complex components of the impedance. In yet another example, the impedance data can include, for each of the multiple frequencies, the voltage and current measurements, which can be used to determine the impedance.

Supervision unit 1150 can provide the impedance data and other data to remote external system 130. In this example, remote external system 130 can be a cloud-based system that monitors the SOH of energy source 206 and energy sources of other systems. For example, remote external system 130 can be a cloud-based system that monitors the SOH of batteries of many EVs. In another example, external device 104 can be a cloud-based system that monitors energy sources 206 of stationary or mobile charging stations or energy sources 206 used in other stationary or mobile applications. Supervision unit 1150 can include a communication interface, e.g., a mobile router, wi-fi router, mobile hotspot, Ethernet interface, or other appropriate interface for sending and receiving data to other devices.

Along with the impedance data, supervision unit 1150 can provide, to remote external system 130, additional data that can be used to determine the SOH of energy source 206. For example, the additional data can include the temperature of energy source 206 when the voltage and current measurements were taken (which can be obtained from a temperature sensor, e.g., a temperature sensor of a BMS for a battery or battery module), the SOC of energy source 206 when the voltage and current measurements were taken, and/or other appropriate data.

Remote external system 130 can use the received data to determine the SOH of energy source 206. In some embodiments, remote external system 130 can maintain lookup tables 1160 or other appropriate data structures to determine the capacity of an energy source 206 based on the received information. For example, as described in more detail below, a lookup table 1160 can map impedance and other data to capacities for energy sources having a particular configuration, e.g., a particular model of batter or particular battery module that includes multiple batteries. Remote external system 130 can use the appropriate lookup table 1160 to determine the capacity of energy source 206 based on the received information. A key value index can also be used as the data structure where the keys are tuples of impedance, temperature, and SOC and the values are the corresponding capacities for those combinations of parameters.

As the capacity of an energy source 260 typically degrades over time and over the course of use, remote external system 130 can maintain a lookup table for each of multiple capacities of energy source 206. In an example embodiment, remote external system 130 can maintain, for each energy source configuration, multiple lookup tables 1160 with each one corresponding to a particular capacity. Each lookup table 160 can map the impedance of energy source 206 to the temperature and SOC of energy source 206 at the time the impedance measurement was taken. Remote external system 130 can compare a new impedance measurement and its corresponding temperature and SOC to the lookup tables and identify a matching lookup table and determine, as the capacity of energy source, the capacity corresponding to the matching lookup table. As described below, the matching can be a closest match rather than requiring an exact match.

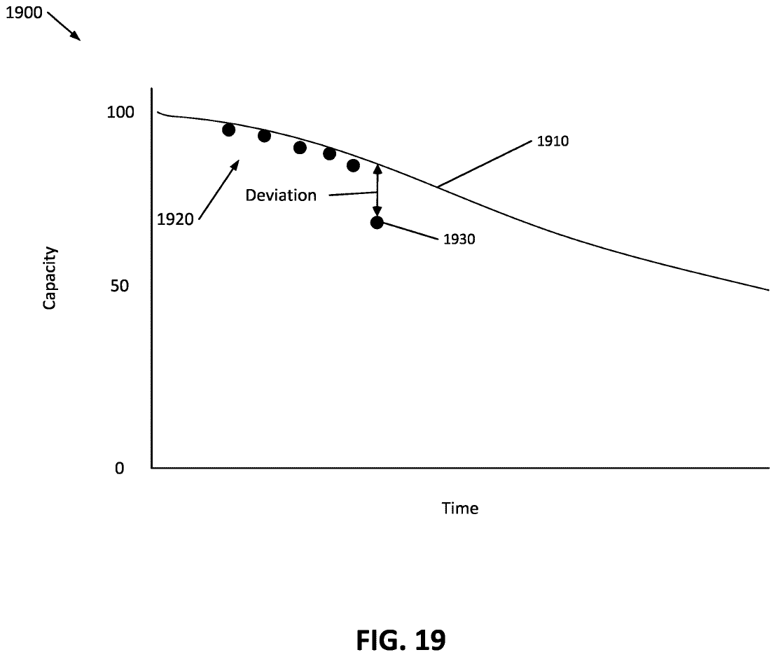

Remote external system 130 can also determine the SOH of energy source 206 based on the capacity and/or other information. For example, remote external system 130 can compare the determined capacity to an estimated capacity based on the age of energy source 206. The age can be in terms of time and/or usage. In an example embodiment, remote external system 130 can maintain, for each energy source configuration, the estimated capacity for energy source for multiple ages. For example, this information can be represented as a plot, as shown in FIG. 19. If the capacity of energy source 206 determined based on its most recent impedance measurement deviates from the estimated capacity for the age of energy source 206, remote external system 130 can determine that the SOH for energy source 206 is low or degraded. For example, if the determined capacity of energy source 206 is at least a threshold amount less than the estimated capacity, remote external system 130 can determine that the SOH for energy source is low or degraded.

As described above, impedance measurements as different frequencies can indicate different types of degradations. Remote external system 130 can determine the SOH for energy source 206 using impedance measurements for many different frequencies. For example, remote external system 130 can perform the process described above using lookup tables to determine the capacity of energy source based on the impedance measurement at each frequency. If the capacity for a particular frequency is low (e.g., at least a threshold amount lower than the estimated capacity), remote external system 130 can determine, as part of the SOH for energy source 206, that energy source 206 has the degraded condition associated with that frequency.

In some example embodiments, remote external system 130 and/or supervision unit 1150 can perform actions based on the determined SOH. For example, supervision unit 1150 can bypass a degraded energy source 206 or module 108 that includes a degraded energy source 206. In another example, remote external system 130 can adjust the control of modules 108 based on the SOH of an energy source 206. For example, supervision unit 1150 can send instruction information to MCD 112 that includes a degraded energy source 206 to reduce the output of the module 108 that includes the degraded energy source 206.

FIG. 12A is a block diagram depicting an example embodiment of a perturbation generator 1108. Perturbation generator 1108 can include a series of shift registers 1202, which receive and record the output of the previous shift register 1202 each clock cycle. A feedback loop with one or more exclusive or (XOR) gates 1204 can be used to generate a pseudo-random signal at the output of perturbation generator 1108. The PRBS signal can have a broad bandwidth, simulating white noise, and a predetermined length before it repeats based on the tap locations 1206.

For example, a perturbation generator 1108 with 13 shift registers 1202, and taps 1206 located at the zero, second, third, and twelfth positions will yield a pseudo random sequence that is 8,191 clock cycles. Similarly, a perturbation generator 1108 with 23 shift registers 1202, and taps 1206 located at the fourth, and twenty-second positions will yield a pseudo random sequence that is 8,388,607 clock cycles.

Perturbation generator 1108 can be clocked at a frequency that results in the generated PBRS signal being a wideband signal, with a maximum frequency of less than or equal to one half of the switching frequency of converter 202 being perturbed (e.g., converter 202 of FIG. 11). In this manner, the natural bandwidth of converter 202 is not saturated by the perturbation signal and avoids degradation of the perturbation and impedance measurement.

FIG. 12B is a plot 1260 depicting an example frequency response of a perturbation signal. As shown in FIG. 12B, the frequency response includes a substantially flat section 1262 up to a particular frequency Fb. This frequency Fb can represent the highest frequency of interest for measuring the impedance of energy source 206. After this frequency, the amplitude rolls off for higher frequencies as show in the roll off section 1264. Injecting the perturbation reference at the two locations described with reference to FIG. 11 provides this frequency response for the frequency band of interest.

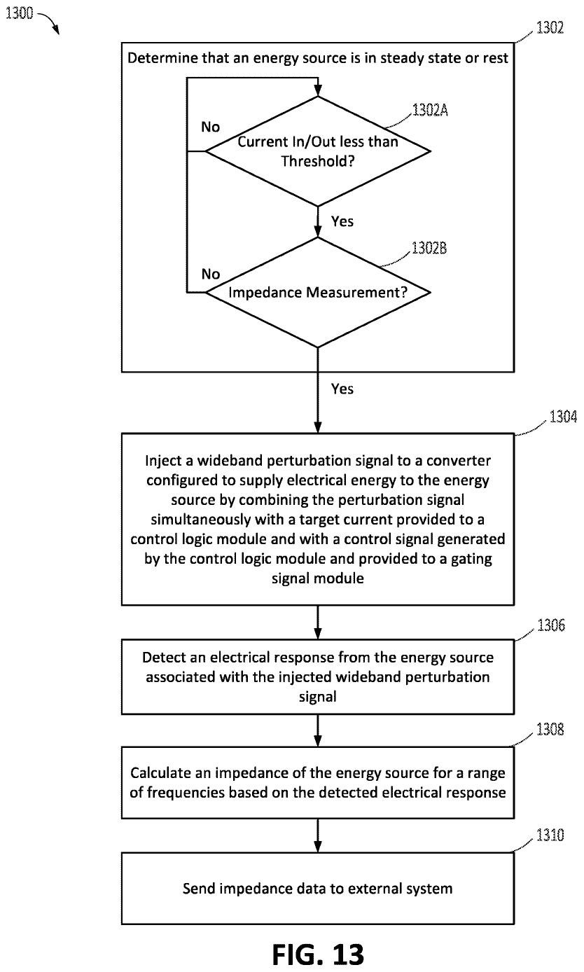

FIG. 13 is a flowchart illustrating an example embodiment of a method 1300 of measuring energy source impedance. The method can be performed by system 100 in any and all of the mobility and stationary applications described elsewhere herein. Method 1300 can be executed by, for example, control system 102 of FIG. 11 or any other control system described herein to measure the impedance of any energy source 206 described herein.

At step 1302, a determination or verification can be made that an energy source 206 (e.g., a battery cell, battery module, fuel cell, HED capacitor) is at steady state or at rest. The determination can be an affirmative determination, e.g., made by reference to the current voltage and current state of the source 206, or the determination can be implicit, such as if control system 102 is programmed to perform the impedance measurement only during a time that system 102 is not operating the respective converter 202 of the module 108 having the source 206 being measured, thus implicitly at a time when source 206 is at rest. Energy source 202 can be a stationary energy storage solution (e.g., a stationary battery, or building backup system) or a mobile one (e.g., the battery pack of an electric vehicle). In some embodiments, for active determination, one or more sensors can periodically or continuously monitor energy source 206 to determine whether energy source 206 is in a steady state.

The term “steady state” can be defined as outputting or receiving less than a threshold amount of power or current. For example, energy source 206 can be considered at steady state whenever there is less than five amps of current flowing to or from energy source 206. In some embodiments, the at rest threshold may be higher (e.g., 50A, or 100A), for example, in large industrial storage solutions, resting current may be much greater than in smaller applications. Similarly, the at rest threshold may be lower than 5A (e.g., 1A, or 2 mA). Thus, the threshold can be application specific.

At step 1302A, if it is determined that the energy source is not at steady state, process 1300 can idle, waiting for the next periodic check, or continue to monitor energy source 206. If energy source 206 is determined to be at steady state, then process 1300 can proceed to step 1302B, where it is determined whether to generate an impedance measurement. If an impedance measurement is not warranted (e.g., one has been recently performed, or it is determined that energy source 206 does not need one at this time), control system 102 can determine to not generate an impedance measurement and process 1300 returns to step 1302A and continues to monitor energy source 206. If an impedance measurement is to be performed, process 1300 proceeds to step 1304.

At step 1304, control system 102 controls converter 202 to introduce a perturbation signal, e.g., a wideband perturbation signal, into the current of energy source 206. The perturbation signal can be based on a perturbation reference (e.g., a PRBS signal) that approximates white noise, and can be introduced, e.g., via switching signals received from LCD 114, to cause converter 202 to induce a transient response by energy source 206. Converter 202 performs energy conversion based on received switching signals that account for a reference signal (e.g., a modulated reference signal) and the perturbation signal. For example, as described herein, LCD 114 can generate the switching signals for converter 202 based on control information received from MCD 112, which can be modified by combining a gain adjusted perturbation reference with the reference signal of the control information.

As described herein, the perturbation reference can be applied to both the reference (or target) signal input to primary controller 1104 of MCD 112 and the input of LCD 114 that generates the switching signals. By applying the perturbation reference to the reference input of primary controller 1104, lower frequency signals are not automatically filtered, rejected, or significantly attenuated by the control algorithm of primary controller 1104. Similarly, the perturbation reference is applied at the output of primary controller 1104, directly to LCD 114 in order to preserve high frequency signals within the perturbation reference, which might not be captured by the control algorithm of primary controller 1104, which may have a relatively limited frequency response. While the perturbation reference is simultaneously injected in two paths, each path can be associated with an individual gain, allowing flexibility to adjust the gain values to balance the frequency response based on the control algorithm and LCD 114.

At step 1306, the transient response induced in energy source 206 is detected. For example, impedance measurement unit 1106 can monitor and record current and voltage at energy source 206 for multiple frequencies in response to the perturbation signal.

At step 1308, the impedance measurement unit 1106 can calculate an impedance of energy source 206 based on the transient response to the perturbation signal. Impedance measurement module 1106 can determine a frequency response of energy source 206, or an ohmic resistance at a range of frequencies along with a phase shift. In some embodiments, this impedance calculation is performed using a Fourier Transform, or a Fast-Fourier Transform, and provides a wideband impedance measurement for energy source 206. This impedance value can be used to determine a health or status of energy source 206. For example, if the impedance is significantly higher or significantly lower than a previous impedance measurement and energy source 206 is a battery, this can be an indication of battery cell degradation.

In some embodiments, MCD 112 or LCD 114 can maintain a reference impedance of energy source 206 for multiple frequencies or multiple frequency ranges. The reference impedances can represent normal impedances of energy source 206 when operating optimally, e.g., without any substantial degradation. To determine the status of energy source 206, MCD 112 or LCD 114 can compare the impedance measurement for each frequency or frequency range to its reference. If any impedance measurement differs from its reference by at least a threshold amount, MCD 112 or LCD 114 can determine that energy source 206 is experiencing a degradation. As the impedance measurements at different frequencies or frequencies ranges can indicate different types of degradations, generating wideband frequency measurements as described herein enables accurate detection of a wide range of degradations or other statuses of energy sources 206.

At step 1310, impedance data that represents the impedance is sent to remote external system 130. For example, MCD 112 can send the impedance data and additional data to supervision unit 1150 and, in turn, supervision unit 1150 can send the impedance data and additional data to remote external system 130. As described herein, remote external system 130 can determine the SOH of energy source 206 based on the data.

### Online Impedance Measurement Examples Using AC Harmonics

In some embodiments, during normal operation (e.g., discharging) of an energy source 206 that is supplying AC electrical energy via converter 202, harmonic frequencies associated with the AC energy can be observed at the terminal of energy source 206. For example, a natural response of converters 202 can be to introduce currents at harmonic frequencies, e.g., including at the second harmonic frequency, of the AC energy being provided by converter 202 to load 101. As described herein, modules 108 can be arranged in arrays 700, e.g., one array for each phase. Converters 202 of modules 108 of each array 700 can cause a non-constant power to be observed on each phase, which also results in harmonic currents at energy source 206 of each module 108.

In some embodiments, the frequency of the AC voltage provided to load 101 varies over time. For example, the frequency of the AC voltage provided to the motor of an EV can vary based on the frequency of the motor. These varying voltages result in harmonic currents having different frequencies being observed at the energy source 206 that provides AC energy to load 110 via converter 202.

By measuring the current and voltage at a harmonic frequency, an impedance of energy source 206 can be determined. This impedance measurement can be performed during operation, and without any particular dedicated equipment for measurement. In other words, existing architecture (e.g., of MCD 112 and module 108) can perform this measurement without interrupting operation of the system 100 and without additional hardware.

During discharge operations where energy source 206 is supplying power through converter 202, the voltage at the energy source 206 will oscillate as a function of the frequency of the AC energy being supplied by converter 202. Similarly current from the energy source 206 will have an AC component, which oscillates out of phase with the voltage. The current frequency at the second harmonic is twice the frequency of the AC energy supplied by converter 202 (e.g., fₑₛ=2f_{conv_output}). If load 101 operates at a range of frequencies between approximately 0-750 Hz, then the range of second harmonic current frequencies at energy source 206 will be approximately 0-1.5 kHz, which is sufficient for a broad impedance characterization of energy source 206. Additionally, there will be a phase difference between the voltage at energy source 206 and the frequency at energy source 206 due to the reactive component of the impedance of energy source 206.

During operation, for a given frequency, a controller (e.g., MCD 112) recording voltage and current measurements for energy source 206 can determine an impedance

$$( e . g . , Z ( f ) = \frac{V ( f )}{I ( f )} )$$

of energy source 206. Over a broad range of operational speeds of an EV motor or other load 101, and with multiple samples, control system 102 and/or remote external system 130 can develop an accurate impedance profile for energy source 206. For example, as the frequency of an EV motor changes as the speed of the EV changes, the frequency of each harmonic changes and an impedance measurement can be obtained for these various speeds and corresponding harmonic frequencies.

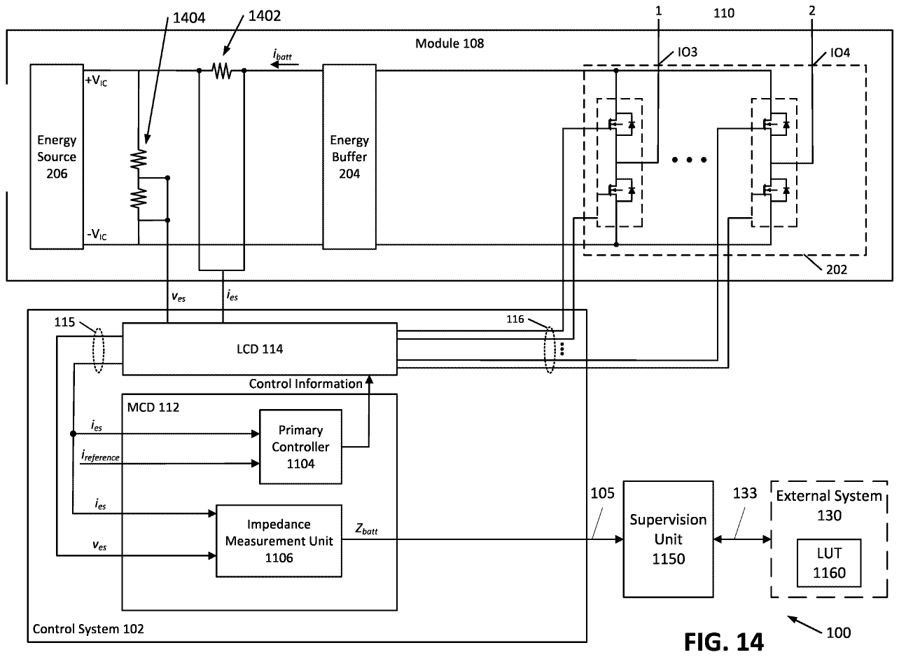

FIG. 14 is a block diagram depicting an example embodiment of an energy system 100 having a control system 102 configured to perform online impedance measurement. Here, control system 102 measures impedance of energy source 206 based on the harmonic current introduced by converter 202 without using the active perturbation described with reference to FIGS. 11-13. In some example embodiments, the impedance is measured using the voltage and current of energy source 206 at the second harmonic relative to the fundamental frequency of the AC energy provided to load 101 as the voltage and current levels at this harmonic are typically higher than other harmonic frequencies. However, other harmonic frequencies can also be used.

In this embodiment control system 102 does not include a perturbation generator 1108. Primary controller 1104 generates control information based on a reference signal (i_{reference}), e.g., without any added perturbation signal for impedance measurement, and LCD 114 generates switching signals for switches of converter 202 based on the control information received from primary controller 1104.

In this embodiment, impedance measurement unit 1106 measures the current of energy source 206 using a shunt resistor 1402. Impedance measurement unit 1106 also measures the voltage of energy source 206 using a voltage divider 1404. Although not shown in FIG. 11, system 100 of FIG. 11 can use the same or similar components in the same or a similar arrangement for voltage and current measurements. Impedance measurement unit 1106 can determine the impedance as described herein, e.g., with reference to FIG. 11.

Impedance measurement unit 1106 can measure the current and voltage using a high sampling rate, e.g., 1 sample per minute, 1 sample per second, 10 k samples per second, 100 k samples per second, or another appropriate rate. In EV embodiments, the times that the frequency of the motor is within a particular frequency range (e.g., within a lower frequency range corresponding to slow speeds of the EV) may be brief. Thus, the high sampling rate can be important in EV embodiments and other embodiments in which time spent in certain frequency ranges is low to ensure that impedance measurements are generated in all frequency ranges of interest.

Similar to the embodiment of FIG. 11, system 100 of FIG. 14 includes a supervision unit 1150 communicably coupled to a remote external system 130. In this example embodiment, supervision unit 1150 can provide impedance data and the additional data described with reference to FIG. 11 to remote external system 130. The additional data can also include, for each impedance measurement, the frequency of the second harmonic when the impedance measurement was taken. For example, supervisory unit 1150 can determine the frequency of the second harmonic based on the output frequency of converter 202. In a particular example, supervision unit 1150 can control MCD 112 and corresponding MCDs 112 of other modules 108 for an EV. Supervision unit 1150 can send control information to each MCD 1150 that includes a reference waveform and/or target output frequency for controlling the motor(s) of the EV. In this example, supervision unit 1150 can compute the second harmonic frequency by simply multiplying the target output frequency at the time the measurements are taken by two. In another example, system 100 can include a frequency and/or phase detector can be electrically coupled to the terminals of energy source 206 or between energy buffer 204 and energy 206 to measure the actual second harmonic frequency and provide the measurements to supervision unit 1150, e.g., by way of MCD 112.

In some example embodiments, the voltage and current measurements can be taken over a single period of the second harmonic AC signal at energy source 206. For example, LCD 114 can include a zero cross detector or peak detector that can be used to identify zero crossings of the current and/or voltage or the peaks of the current and/or voltage.

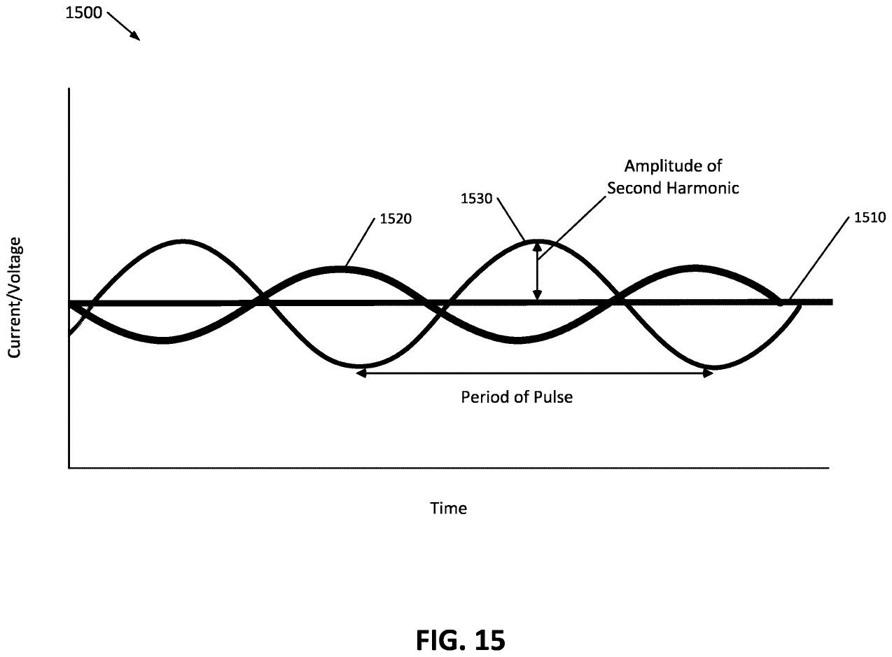

FIG. 15 is a plot 1500 depicting an example harmonic voltage 1520 and an example harmonic current 1530 of an energy source 206. As shown in FIG. 15, the voltage and current is out of phase due to the reactive component of the impedance of energy source 206. Both the voltage 1520 and the current 1530 oscillate above the corresponding DC component 1510 such that the average of voltage 1520 equals the DC voltage of energy source 206 and the average of current 1530 equals the DC current of energy source 206.

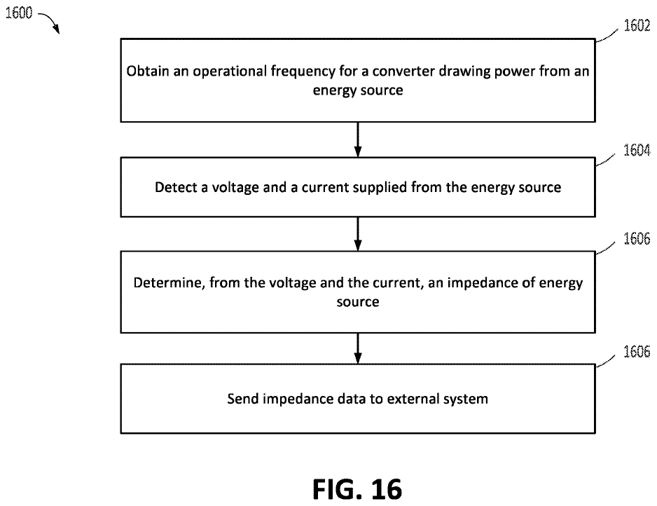

FIG. 16 a flowchart illustrating an example embodiment of a method 1600 of measuring energy source impedance using AC harmonics. Method 1600 can be performed by, for example, control system 102 of FIG. 11 or any other control system described herein to measure the impedance of any energy source 206 described herein.

At step 1602, an operational frequency for converter 202 that is discharging an energy source 206 is obtained. Converter 202 can be converting DC electricity from energy source 206 to AC electricity to supply one or more loads (e.g., via IO ports IO3 and IO4). In some embodiments, converter 202 is supplying an electric motor that is controlled based on the AC frequency provided by converter 202. For example, to cause the motor to accelerate, converter 202 can increase its output frequency.

At step 1604, a voltage and current being supplied from the energy source 206 are detected. In some embodiments, the voltage is measured using a voltage divider, in which the voltage drop across one of a pair of known resistors connected in parallel with energy source 206 is measured. The current can be measured using a shunt resistor, which provides a small voltage drop as current flows through, and therefore a total current can be measured as a function of the voltage drop across the shunt resistor.

At step 1606, an impedance at the energy source is determined based on the detected voltage and current. The impedance can be determined for a frequency of AC current observed at energy source 206. For example, the impedance can be determined for the second harmonic frequency. For the determined frequency, an impedance can be determined by dividing the voltage output at that frequency by the current at that frequency. This can be represented by the equation

$$Z ( f ) = \frac{V ( f )}{I ( f )} .$$

At step 1612, impedance data that represents the impedance is sent to remote external system 130. For example, MCD 112 can send the impedance data and additional data to supervision unit 1150 and, in turn, supervision unit 1150 can send the impedance data and additional data to remote external system 130. As described herein, remote external system 130 can determine the SOH of energy source 206 based on the data.

### Examples of Determining the SOH of an Energy Source Based on Impedance Measurements

One example characteristic that is particularly indicative of the SOH of an energy source 206 is the capacity of the energy source 206. As an energy source 206 ages, e.g., over time and/or based on use, the capacity of the energy source 206 typically drops. Impedance measurements can be used to determine the capacity of an energy source 206. For example, the impedance of an energy source 206 can be proportional to its capacity.

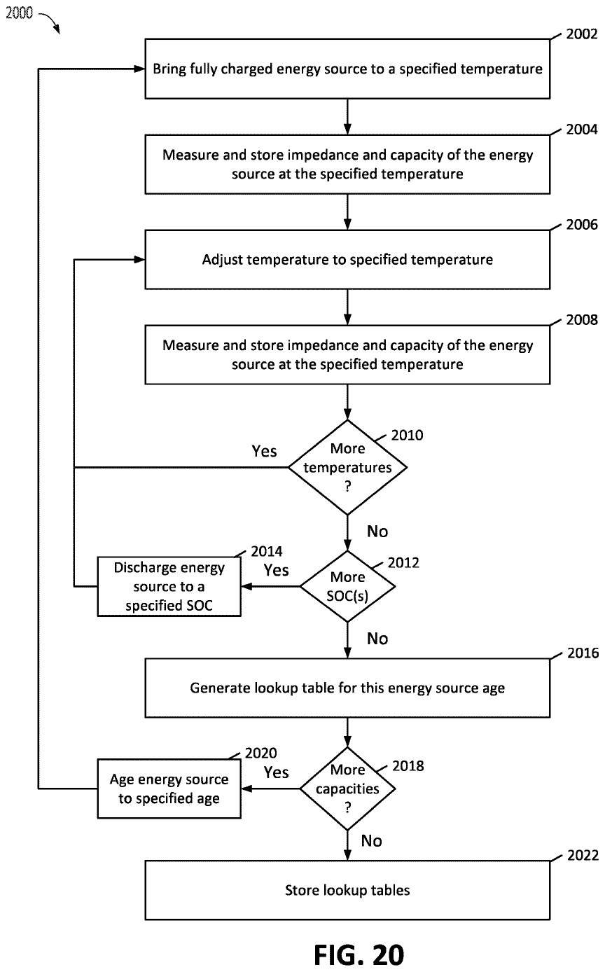

The impedance of an energy source 206 can vary based on temperature of energy source 206 and the SOC of energy source 206. To determine the capacity of energy source 206, a tuple of data that includes the measured impedance of energy source, the temperature of energy source 206 when the impedance measurement was taken, and the SOC of energy source 206 when the impedance measurement was taken can be compared to a lookup table that maps corresponding tuples of data to capacities of energy source 206. The lookup tables can be generated based on actual observations for energy sources having the same configuration as the energy source 206 being monitored. For example, a manufacturer of an energy source 206 or another entity (e.g., independent evaluator) can generate the lookup tables using process 2000 described below with reference to FIG. 20.

Impedance measurements can also be used to detect particular degradations and/or determine other characteristics of energy source 206. For example, impedance deviations at particular frequencies of AC current at energy source 206 can be used to determine the type of degradation of energy source 206. The impedance data can also be used to generate an impedance profile for energy source 206 that can be used to detect these deviations. The impedance data can also be used to estimate the capacity of energy source 206, estimate SOH (e.g., using capacity that is determined based on impedance), estimate SOC using the impedance and temperature, enhance SOC estimation algorithms, estimate the temperature of energy source 206 without a thermal sensor, detect rapid battery failures (e.g., using drops in capacity or other deviations), and/or to detect or measure other characteristics of energy source 206.

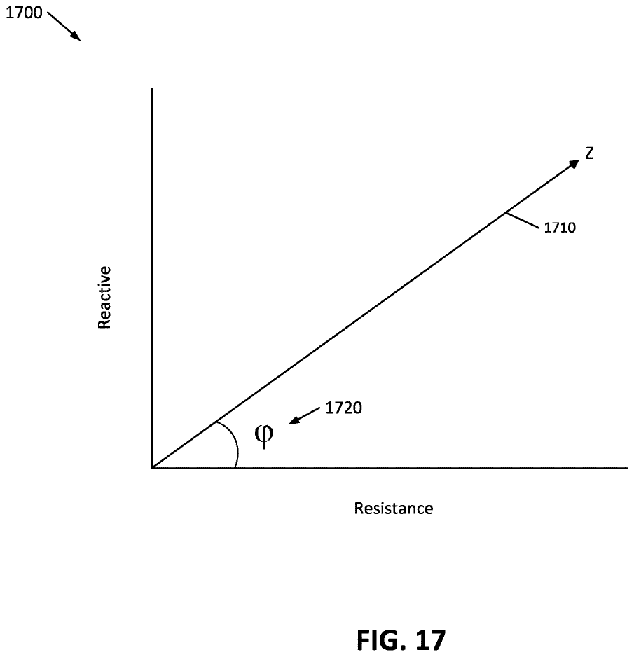

FIG. 17 is a plot 1700 depicting an example impedance vector 1710 and phase angle 1720, which can be referenced using the symbol q. As shown in FIG. 17, the impedance of energy source 206, e.g., of a battery or battery module, can include a resistive and reactive component. The vector 1710 represents the magnitude of both components and the angle 1720 represents the relative magnitude of each component. The magnitude of the impedance is the modulus or the length of the vector 1710.

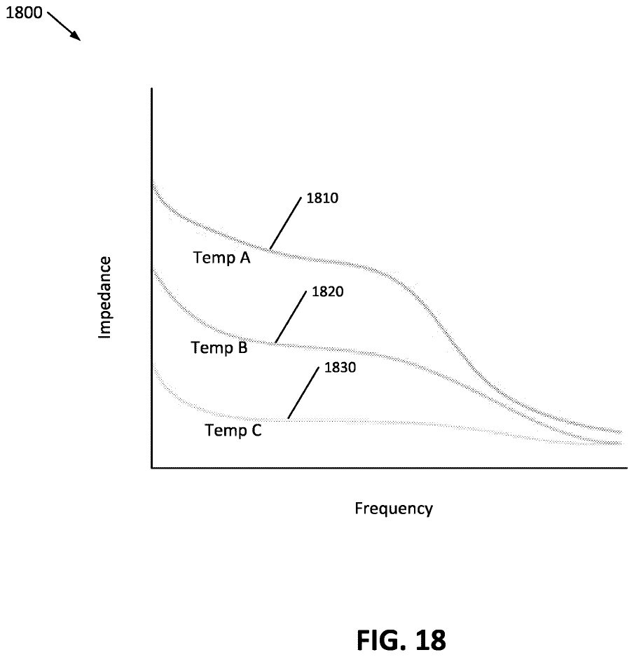

FIG. 18 is a plot depicting example energy source impedances 1810-1830. As shown in FIG. 18, the impedance of an energy source 206 can vary with a change in temperature of energy source 206. Systems 100 described herein can measure temperature along with impedance so that the capacity and SOH can be determined accurately based on the temperature of energy source 206 when the impedance measurements are taken.

FIG. 19 is a plot 1900 depicting example changes in the capacity 1910 of an energy source 206 over time. As batteries age, the capacity tends to drop in a predictable manner. As described below with reference to FIG. 20, the changes in capacity can be measured to produce the plot 900 for each configuration of an energy source 206. This data along with impedance measurements of an energy source 206 having a particular configuration can be then be used to determine whether the energy source 206 is deviating from the predicted capacity, which can then be used to determine SOC and corrective actions (e.g., bypassing the energy source 206).

In the example shown in FIG. 19, early determined capacities 1920 for an energy source 206 appear to follow the predicted capacity 1910 for the energy source 206. However, the determined capacity 1930 shows a significant deviation from the predicted capacity at that age of the energy source 206. This can be due to one or more degradations with the energy source 206, which can be identified based on the frequency at which the deviation is detected. For example deviations detected for low frequencies can correspond to capacitive-related degradations, while middle frequency range deviations can correspond to resistive-related and/or chemical degradations, and high frequency deviations can correspond to inductive-related degradations.

FIG. 20 is a flowchart illustrating an example embodiment of a method 2000 of generating lookup tables for determining the capacity of an energy source 206. Method 2000 can be performed by, for example, control system 102 of FIG. 11 or any other control system described herein to measure the impedance of any energy source 206 described herein. Method 2000 can also be performed by a system configured to cycle energy source 206 over time and generate impedance measurements for energy source 206 periodically. For brevity, method 2000 is described as being performed by a system.

In general, method 2000 can be used to generate multiple lookup tables for an energy source 206. Each lookup table can map the impedance of energy source 206 at a particular temperature and particular SOC to that particular temperature and particular SOC, and to the capacity corresponding to the lookup table. As the capacity of energy source 206 tends to degrade over time, method 2000 can be used to generate a respective lookup table for each of multiple capacities of energy source 206.

In this example, the system can generate the lookup tables by starting with a new energy source 206 that is full charged. However, the steps related to adjusting SOC described below can be reversed such that energy source 206 is completely discharged initially or at some in between SOC. This energy source can also be referred to as a test energy source that is tested to generate the lookup tables. The system can generate a lookup table for this 100% capacity state by adjusting the temperature and SOC of energy source and measuring the impedance of energy source 206 for each combination of temperature and SOC. Each impedance measurement can be taken over a single cycle of AC energy (or just a few cycles) such that performing the steps to generate each impedance measurement does not significantly affect the temperature or SOC of energy source 206.

After obtaining all of the impedance measurements for the 100% capacity state, the system can generate the lookup table for this capacity. The system can then age energy source 206 by cycling energy source 206 may times over a specified time period to get to the next capacity for which a lookup able will be generated. Cycling energy source 206 can include charging and discharging energy source 206, e.g., between fully charged and fully discharged states or between differing change states). The system can then perform the same process of varying the temperature and SOC for this capacity and generating a lookup table using impedance measurements for each combination of temperature and SOC. The system can repeat this process until a lookup table has been generated for each capacity for which a lookup table is being generated.

The system can generate lookup tables for each configuration of energy sources 206, e.g., rather than for each individual cell. As the connections between individual battery cells can include corresponding impedances, generating the lookup tables using the actual configuration provides more accurate capacity estimations.

At step 2002, a fully charged energy source 206 is brought to a specified temperature for impedance measurement (2002). The system can have a list of temperatures for which impedance measurements are to be taken, which can be in the form of a sequence. The system can bring energy source 206 to the temperature for the measurement in the sequence that is to be taken in this iteration. For battery modules (and other energy sources), the system can adjust the temperature of a chamber (or other housing) in which the battery module is located to the specified temperature and wait a specified amount of time (e.g., 30 minutes, one hour, or another appropriate duration) to ensure that all cells are at the specified temperature before measuring the impedance of energy source 206.

At step 2004, the system measures the impedance of energy source 206. The system can inject an AC current of a particular frequency onto the terminals of energy source 206 and measure the impedance of energy source at that frequency. In another example, the system can inject PRBS-based AC signal onto the terminals of energy source 206 and measure the impedance at multiple frequencies. In general, the system can obtain the impedance measurement from a single cycle of the AC signal for each frequency to avoid changing the temperature and/or SOC of energy source 206. The system can store the impedance measurement with a reference to the temperature and the SOC of energy source 206 when the impedance was measured and with a reference to the capacity of energy source 206. In this way, the stored data can be used to generate a lookup table for the capacity.

At step 2006, the system adjusts the temperature of energy source 206 to a specified temperature. For example, the system can adjust the temperature of the chamber to the next temperature in the sequence and wait the specified amount of time.

At step 2008, the system measures the impedance of energy source. The system can measure the impedance as described with reference to step 2004. The system can store the impedance measurement with a reference to the temperature and the SOC of energy source 206 when the impedance was measured and with a reference to the capacity of energy source 206.

At step 2010, the system determines whether there are additional temperatures for which an impedance measurement is to be made. For example, the system can determine whether there are any additional temperatures in the list or sequence for which to obtain an impedance measurement for the lookup table for the current capacity. If so, method 2000 returns to step 2006 to adjust the temperature of energy source 206 for the next impedance measurement.

If not, method proceeds to step 2012. In step 2012, the system determines whether there are additional SOCs for which an impedance measurement is to be made. Similar to temperatures, the system can obtain impedance measurements for a list or sequence of SOCs of energy source 206. The system can perform steps 2006-2014 until impedance measurements are obtained for each combination of temperature and SOC that is to be included in the lookup table.

If there are additional SOCs for which an impedance measurement is to be made, method proceeds to step 2014. In step 2014, the system discharges the energy source to a specified SOC. For example, the system can discharge energy source to the next SOC in the sequence. In some implementations, the system can monitor the SOC of energy source 206 by estimating the SOC of energy source using an open circuit voltage curve for energy source 206. Once energy source 206 reaches the SOC, the system can stop discharging energy source 206 and method can proceed to step 2006. In step 2006, the system can return energy source 206 to the first temperature in the sequence. This restarts the collection of impedance measurements for each temperature for the updated SOC of energy source 206.

If there are no additional SOCs in step 2012, the system generates a lookup table for the current capacity of energy source 206. For the first cycle through steps 2002-2020, the system generates a lookup table for the full capacity state. This lookup table can map the measured impedances for the full capacity energy source to the temperatures and SOC for which the impedance measurements were obtained.

In step 2018, the system determines whether there are additional capacity states for which a lookup table is to be generated. For example, the system can generate lookup tables for a specified list of capacity states, which can be in the form of a sequence.

If there additional capacity states, method proceeds to step 2020. In step 2020, the system ages energy source 206 to reduce the capacity of energy source 206. In some embodiments, the system can age energy source 206 by cycling energy source multiple times, e.g., continuously, over time until energy source reaches the next capacity in the list or sequence. After aging energy source 206 to the target capacity, method proceeds to step 202 to obtain the impedance measurement for generating the lookup table for this capacity.

If there are no additional capacity states, method 2000 proceeds to step 2022. In step 2022, the system can store the lookup tables. The system can also deploy the lookup tables for each energy source to remote external system 130 for monitoring the capacity and SOH for energy sources having the same configuration as energy source 206 for which the lookup tables were generated.

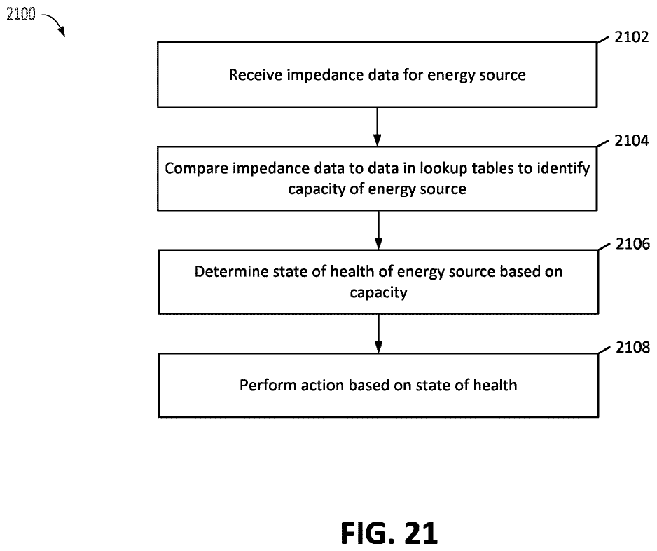

FIG. 21 is a flowchart illustrating an example embodiment of a method 2100 of determining the state of health (SOH) of an energy source and performing an action based on the SOH. Method 2100 can be performed by remote external system 130, control system 102, or another appropriate system.

In step 2102, impedance data for an energy source 206 is received. As described above, the impedance data can represent an impedance measurement, which can take various forms. For example the impedance measurement can be in the form of a vector (or the modulus of the vector) that represents the resistive and reactive components of the measured impedance and the phase angle (q) between the resistive and reactive components. The impedance data can include, for each of the multiple frequencies, the values for the real and complex components of the impedance. In another example, the impedance data can include, for each of the multiple frequencies, the voltage and current measurements, which can be used to determine the impedance.

The impedance data can also include, or be accompanied by, additional data. The additional data can include the temperature of energy source 206 when the impedance measurement was taken and the SOC of energy source 206 when the impedance measurement was taken. The additional data can also include the age of energy source 206.

In step 2104, the impedance data is compared to data in lookup tables for energy sources having the same configuration as energy source 206. For example, the system can identify the lookup tables for the various capacity states for the energy sources having that configuration. The system compares the impedance, temperature, and SOC of the impedance data to corresponding values in the lookup tables to identify a lookup table that has the closest match between the three parameters. For example, the closest match may be the lookup table having the smallest total difference between the three values. The system can then determine that the current capacity of energy source is the capacity corresponding to the closest matching lookup table.

In step 2106, the SOH of energy source 206 is determined. The SOH of energy system can be determined based on the capacity. For example, remote external system 130 can compare the capacity to an estimated capacity for energy source 206 based on the age of energy source 206. If the determined capacity is within a threshold of the estimated capacity, the system can determine that energy source 206 is healthy. If the determined capacity is more than a threshold amount lower than the predicted capacity, remote external system 130 can determine that energy source 206 is degraded. Remote external system 130 can also consider other factors when determining the SOH of energy source 206, such as deviation from predicted decay rate of energy source 206.

In some example embodiments, if the capacity is more than a threshold amount lower than the predicted capacity, remote external system 130 can send instructions to MCD 112 via supervision unit 1150 to obtain additional impedance measurements and to provide impedance data for the impedance measurements to remote external system 130. In this way, remote external system 130 can evaluate those measurements to ensure that the low capacity measurement is accurate.

In step 2108, an action is performed based on the SOH of energy source 206. For example, if the SOH is degraded, remote external system 130 can instruct MCD 112 to bypass energy source 206 or the module 108 that includes energy source 206. In another example, remote external system 130 can send, to supervision 1150, information indicating the SOH of energy source 206. Supervision unit 1150 can then determine whether to perform any actions based on the SOH of energy source 206. For example, supervision unit 1150 can instruct MCD 112 to adjust the output of energy source 206 or its module 108 if energy source 206 is degraded. If energy source 206 has a normal SOH, supervision unit 1150 can continue operating energy source 206 and its module 108 normally.

Although the example lookup tables and methods 2000 and 2100 are described in terms of impedances, temperatures, and SOCs, the lookup tables can be configured to map just the impedance to capacity, or the impedance and one of the other two parameters to capacity. In other examples, additional parameters can also be used.

Remote external system 130 can store multiple impedance measurements for each energy source 206 being monitored. By maintaining a record of historic impedances, averaging can be performed to reduce measurement noise. Additionally, long term trends can be identified, potentially providing an early indication of future maintenance (e.g., cells that need to be replaced or an indication that energy source 206 is nearing end of life). Remote external system 130 can also generate an impedance profile for each energy source 206. For example, the impedance profile can include time series data of impedances for multiple frequencies or frequency ranges over the course of operation of system 100 that includes energy source 206.

The impedance measurements of energy source 206 can be used to determine or estimate characteristics of energy source 206. For example, the impedance of a battery or other energy source 206 can vary across the lifetime of energy source 206. The change in impedance can be due to the SOH of energy source over time.

By recording impedance measurements over time and optionally indexing the impedance measurements based on temperature and/or SOC, changes in the impedance can be used to determine or estimate characteristics of energy source 206. For example, control system 102 or remote external system 130 can use the impedance of energy source 206 and/or changes to the impedance over time to estimate the SOH, capacity, SOC, and/or temperature of energy source 206. Control system 102 or remote external system 130 can also differentiate the impedance measurements for energy source 206 to obtain ohmic impedance, electrolyte impedance, activation, and/or diffusion, which can be used to determine the SOH of energy source 206.

Various aspects of the present subject matter are set forth below, in review of, and/or in supplementation to, the embodiments described thus far, with the emphasis here being on the interrelation and interchangeability of the following embodiments. In other words, an emphasis is on the fact that each feature of the embodiments can be combined with each and every other feature unless explicitly stated or taught otherwise.

In many embodiments, an energy system includes an energy source configured to store or discharge electrical energy. The energy system includes a converter that includes a plurality of switches and that is configured to supply or withdraw direct current (DC) electricity from the energy source. The energy system includes a control system configured to provide switching signals to the converter. The control system includes a primary controller configured to generate, based on an input comprising a reference current, control information comprising a reference signal for controlling the switches of the controller to output a target current. The control system also includes a local control device configured to generate the switching signals based on the reference signal. The control system also includes a perturbation generator configured to generate a wideband perturbation reference to inject a perturbation signal at an output of the converter. The control system also includes one or more combiner modules configured to modify at least one of the reference current prior to being input to the primary controller and/or the reference signal prior to being input to the local control device. The control system also includes an impedance measurement unit configured to receive sensed parameters for the energy source and determine an impedance of the energy source based on the sensed parameters.

In some embodiments, the perturbation generator is configured to generate the wideband perturbation reference when the energy source is detected to be at rest and the impedance measurement unit is configured to determine the impedance of the energy source after the perturbation signal is generated.

In some embodiments, the wideband perturbation reference comprises frequencies in a range of 1 Hz to 10 kHz.

In some embodiments, the perturbation generator is configured to generate the wideband perturbation reference based on a pseudo random binary sequence (PRBS).

In some embodiments, the control system includes a first combiner module configured to multiply the wideband perturbation reference by a first gain and adjust the reference current by combining a product of the wideband perturbation reference and the first gain with the reference current.

In some embodiments, the first combiner module is configured to output the adjusted reference current as the input to the primary controller.

In some embodiments, the control system includes a second combiner module configured to multiply the wideband perturbation reference by a second gain and adjust the reference signal by combining a product of the wideband perturbation reference and the second gain with the reference signal.

In some embodiments, the second combiner module is configured to receive the reference signal from the primary controller and provide the adjusted reference signal to the local control device.

In some embodiments, the sensed parameters includes a current of the energy source and a voltage of the energy source.

In some embodiments, the converter is configured to provide energy to and from the energy source during normal operations in addition to during impedance measurement operations.

In some embodiments, the energy source is a first energy source of a first module and the converter is a first converter of the first module and the energy system includes a plurality of modules electrically coupled together in cascaded fashion to form an array,
wherein the array is configured to output an AC signal comprising a superposition of AC module voltages from the plurality of converter modules.

In many embodiments, a method of determining an impedance of an energy source includes injecting a wideband perturbation reference into a converter configured to supply electrical energy to the energy source, wherein the wideband perturbation reference is injected by combining the wideband perturbation reference with (i) a reference current at an input of a primary controller and with (ii) a reference signal generated by the primary controller and provided as input to a local control module configured to generate switching signals for switches of the converter based on the reference signal. The method includes detecting an electrical response from the energy source, the electrical response being a response to an perturbation signal introduced into current of the energy source by converter. The method includes calculating an impedance of the energy source for a range of frequencies based on the detected electrical response.

In some embodiments, the method includes determining that the energy source is at rest, wherein injecting the wideband perturbation reference includes injecting the wideband perturbation reference in response to determining that the energy system is at rest.

In some embodiments, determining that the energy source is at rest comprises determining that a total current flowing to or from the energy source is less than a predetermined threshold.

In some embodiments, the predetermined threshold is less than 5 amps.

In some embodiments, the wideband perturbation reference is a pseudo random binary sequence (PRBS).

In some embodiments, the wideband perturbation reference is multiplied by a first gain prior to being combined with the reference current.

In some embodiments, the wideband perturbation reference is multiplied by a second gain prior to being combined with the reference signal.

In some embodiments, the wideband perturbation reference comprises frequencies in the range of 1 Hz to 10 KHz.

In some embodiments, calculating the impedance of the energy source includes calculating a Fourier Transform of the electrical response.

In some embodiments, the wideband perturbation reference is injected over a period of less than five minutes.

In many embodiments, an energy system includes an energy source configured to store or discharge electrical energy. The energy system includes a converter that includes a plurality of switches and configured to supply or withdraw direct current (DC) electricity from the energy source and to output an alternating current (AC) waveform to a load. The energy system includes an impedance measurement unit configured to obtain sensed parameters for a harmonic frequency of the AC waveform at the energy source and determine an impedance of the energy source based on the sensed parameters.

In some embodiments, the harmonic frequency is a second harmonic frequency.

In some embodiments, the impedance measurement unit is configured to obtain the sensed parameters and determine the impedance of the energy source according to a specified frequency.

In some embodiments, the specified frequency is greater than one measurement per minute.

In some embodiments, the specified frequency is greater than one measurement per second.

In some embodiments, the converter is configured to adjust the frequency of the AC waveform.

In some embodiments, the impedance measurement unit is configured to obtain sensed parameters for each frequency of the AC waveform.

In many embodiments, a method of determining a state of health of an energy source includes receiving impedance data representing an impedance of an energy source and additional data indicating actual values of one or more parameters of energy source at a time the impedance of energy source was measured. The method includes identifying a set of data structures that each map impedances and tested values of the one or more parameters of a tested energy source to a corresponding capacity of the tested energy sources. The method includes comparing the impedance of the energy source and the actual values of the one or more parameters to corresponding values of each data structure. The method includes identifying, based on the comparison, a closest matching data structure and determining the state of health of the energy source based on the capacity corresponding to the closest matching data structure.

In some embodiments, the one or more parameters of the energy source include a temperature of the energy source at the time the impedance of the energy source was measured.

In some embodiments, the one or more parameters of the energy source include a state of charge of the energy source at the time the impedance of the energy source was measured.

In some embodiments, determining the state of health of the energy source includes comparing the capacity corresponding to the closest matching data structure to a predicted capacity for the energy source based on an age of the energy source.

In some embodiments, determining the state of health of the energy source includes determining that the capacity corresponding to the closest matching data structure is greater than a threshold amount lower than the predicted capacity and in response to determining that the capacity corresponding to the closest matching data structure is greater than the threshold amount lower than the predicted capacity, determining that the energy source is degraded.

In some embodiments, the method includes adjusting operation of the energy source or a module that includes the energy source in response to determining that the energy source is degraded.

In some embodiments, the method includes bypassing the energy source or a module than includes the energy source in response to determining that the energy source is degraded.

In some embodiments, the method includes reducing an output of the energy source or a module than includes the energy source in response to determining that the energy source is degraded.

In some embodiments, the method includes receiving impedance data for multiple frequencies of an AC signal at the energy source.

In some embodiments, the method includes determining a particular degraded condition based on the impedance data for a particular frequency of the multiple frequencies.

The term “module” as used herein refers to one of two or more devices or sub-systems within a larger system. The module can be configured to work in conjunction with other modules of similar size, function, and physical arrangement (e.g., location of electrical terminals, connectors, etc.). Modules having the same function and energy source(s) can be configured identical (e.g., size and physical arrangement) to all other modules within the same system (e.g., rack or pack), while modules having different functions or energy source(s) may vary in size and physical arrangement. While each module may be physically removable and replaceable with respect to the other modules of the system (e.g., like wheels on a car, or blades in an information technology (IT) blade server), such is not required. For example, a system may be packaged in a common housing that does not permit removal and replacement any one module, without disassembly of the system as a whole. However, any and all embodiments herein can be configured such that each module is removable and replaceable with respect to the other modules in a convenient fashion, such as without disassembly of the system.

The term “master control device” is used herein in a broad sense and does not require implementation of any specific protocol such as a master and slave relationship with any other device, such as the local control device.

The term “output” is used herein in a broad sense, and does not preclude functioning in a bidirectional manner as both an output and an input. Similarly, the term “input” is used herein in a broad sense, and does not preclude functioning in a bidirectional manner as both an input and an output.

The terms “terminal” and “port” are used herein in a broad sense, can be either unidirectional or bidirectional, can be an input or an output, and do not require a specific physical or mechanical structure, such as a female or male configuration.

Various aspects of the present subject matter are set forth below, in review of, and/or in supplementation to, the embodiments described thus far, with the emphasis here being on the interrelation and interchangeability of the following embodiments. In other words, an emphasis is on the fact that each feature of the embodiments can be combined with each and every other feature unless explicitly stated otherwise or logically implausible.

Processing circuitry can include one or more processors, microprocessors, controllers, and/or microcontrollers, each of which can be a discrete or stand-alone chip or distributed amongst (and a portion of) a number of different chips. Any type of processing circuitry can be implemented, such as, but not limited to, personal computing architectures (e.g., such as used in desktop PC's, laptops, tablets, etc.), programmable gate array architectures, proprietary architectures, custom architectures, and others. Processing circuitry can include a digital signal processor, which can be implemented in hardware and/or software. Processing circuitry can execute software instructions stored on memory that cause processing circuitry to take a host of different actions and control other components.

Processing circuitry can also perform other software and/or hardware routines. For example, processing circuitry can interface with communication circuitry and perform analog-to-digital conversions, encoding and decoding, other digital signal processing, multimedia functions, conversion of data into a format (e.g., in-phase and quadrature) suitable for provision to communication circuitry, and/or can cause communication circuitry to transmit the data (wired or wirelessly).

Processing circuitry can also be adapted to execute the operating system and any software applications, and perform those other functions not related to the processing of communications transmitted and received.

Computer program instructions for carrying out operations in accordance with the described subject matter may be written in any combination of one or more programming languages, including an object oriented programming language such as Java, JavaScript, Smalltalk, C++, C#, Transact-SQL, XML, PHP or the like and conventional procedural programming languages, such as the “C” programming language or similar programming languages.

Memory, storage, and/or computer readable media can be shared by one or more of the various functional units present, or can be distributed amongst two or more of them (e.g., as separate memories present within different chips). Memory can also reside in a separate chip of its own.

To the extent the embodiments disclosed herein include or operate in association with memory, storage, and/or computer readable media, then that memory, storage, and/or computer readable media are non-transitory. Accordingly, to the extent that memory, storage, and/or computer readable media are covered by one or more claims, then that memory, storage, and/or computer readable media is only non-transitory. The terms “non-transitory” and “tangible” as used herein, are intended to describe memory, storage, and/or computer readable media excluding propagating electromagnetic signals, but are not intended to limit the type of memory, storage, and/or computer readable media in terms of the persistency of storage or otherwise. For example, “non-transitory” and/or “tangible” memory, storage, and/or computer readable media encompasses volatile and non-volatile media such as random access media (e.g., RAM, SRAM, DRAM, FRAM, etc.), read-only media (e.g., ROM, PROM, EPROM, EEPROM, flash, etc.) and combinations thereof (e.g., hybrid RAM and ROM, NVRAM, etc.) and variants thereof.

It should be noted that all features, elements, components, functions, and steps described with respect to any embodiment provided herein are intended to be freely combinable and substitutable with those from any other embodiment. If a certain feature, element, component, function, or step is described with respect to only one embodiment, then it should be understood that that feature, element, component, function, or step can be used with every other embodiment described herein unless explicitly stated otherwise. This paragraph therefore serves as antecedent basis and written support for the introduction of claims, at any time, that combine features, elements, components, functions, and steps from different embodiments, or that substitute features, elements, components, functions, and steps from one embodiment with those of another, even if the following description does not explicitly state, in a particular instance, that such combinations or substitutions are possible. It is explicitly acknowledged that express recitation of every possible combination and substitution is overly burdensome, especially given that the permissibility of each and every such combination and substitution will be readily recognized by those of ordinary skill in the art.

As used herein and in the appended claims, the singular forms “a,” “an,” and “the” include plural referents unless the context clearly dictates otherwise.

While the embodiments are susceptible to various modifications and alternative forms, specific examples thereof have been shown in the drawings and are herein described in detail. It should be understood, however, that these embodiments are not to be limited to the particular form disclosed, but to the contrary, these embodiments are to cover all modifications, equivalents, and alternatives falling within the spirit of the disclosure. Furthermore, any features, functions, steps, or elements of the embodiments may be recited in or added to the claims, as well as negative limitations that define the inventive scope of the claims by features, functions, steps, or elements that are not within that scope.

1. An energy system, comprising:
an energy source configured to store or discharge electrical energy;
a converter comprising a plurality of switches and configured to supply or withdraw direct current (DC) electricity from the energy source;
a control system configured to provide switching signals to the converter, the control system comprising:
a primary controller configured to generate, based on an input comprising a reference current, control information comprising a reference signal for controlling the switches of the controller to output a target current;
a local control device configured to generate the switching signals based on the reference signal;
a perturbation generator configured to generate a wideband perturbation reference to inject a perturbation signal at an output of the converter;
one or more combiner modules configured to modify at least one of the reference current prior to being input to the primary controller and/or the reference signal prior to being input to the local control device; and
an impedance measurement unit configured to receive sensed parameters for the energy source and determine an impedance of the energy source based on the sensed parameters.

2. The energy system of claim 1, wherein the perturbation generator is configured to generate the wideband perturbation reference when the energy source is detected to be at rest and the impedance measurement unit is configured to determine the impedance of the energy source after the perturbation signal is generated.

3. The energy system of claim 1 or claim 2, wherein the wideband perturbation reference comprises frequencies in a range of 1 Hz to 10 KHz.

4. The energy system of any preceding claim, wherein the perturbation generator is configured to generate the wideband perturbation reference based on a pseudo random binary sequence (PRBS).

5. The energy system of any preceding claim, wherein the control system comprises a first combiner module configured to multiply the wideband perturbation reference by a first gain and adjust the reference current by combining a product of the wideband perturbation reference and the first gain with the reference current.

6. The energy system of claim 5, wherein the first combiner module is configured to output the adjusted reference current as the input to the primary controller.

7. The energy system of any preceding claim, wherein the control system comprises a second combiner module configured to multiply the wideband perturbation reference by a second gain and adjust the reference signal by combining a product of the wideband perturbation reference and the second gain with the reference signal.

8. The energy system of claim 7, wherein the second combiner module is configured to receive the reference signal from the primary controller and provide the adjusted reference signal to the local control device.

9. The energy system of any preceding claim, wherein the sensed parameters comprise a current of the energy source and a voltage of the energy source.

10. The energy system of claim any preceding claim, wherein the converter is configured to provide energy to and from the energy source during normal operations in addition to during impedance measurement operations.

11. The energy system of claim 1, wherein:
the energy source is a first energy source of a first module and the converter is a first converter of the first module; and
the energy system comprises a plurality of modules electrically coupled together in cascaded fashion to form an array, wherein the array is configured to output an AC signal comprising a superposition of AC module voltages from the plurality of converter modules.

12. A method of determining an impedance of an energy source, the method comprising:
injecting a wideband perturbation reference into a converter configured to supply electrical energy to the energy source, wherein the wideband perturbation reference is injected by combining the wideband perturbation reference with (i) a reference current at an input of a primary controller and with (ii) a reference signal generated by the primary controller and provided as input to a local control module configured to generate switching signals for switches of the converter based on the reference signal;
detecting an electrical response from the energy source, the electrical response being a response to an perturbation signal introduced into current of the energy source by converter; and
calculating an impedance of the energy source for a range of frequencies based on the detected electrical response.

13. The method of claim 12, further comprising determining that the energy source is at rest, wherein injecting the wideband perturbation reference comprises injecting the wideband perturbation reference in response to determining that the energy system is at rest.

14. The method of any of claims 12-13, wherein determining that the energy source is at rest comprises determining that a total current flowing to or from the energy source is less than a predetermined threshold.

15. The method of claim 14, wherein the predetermined threshold is less than 5 amps.

16. The method of any of claims 12-15, wherein the wideband perturbation reference is a pseudo random binary sequence (PRBS).

17. The method of any of claims 12-16, wherein the wideband perturbation reference is multiplied by a first gain prior to being combined with the reference current.

18. The method of any of claims 12-17, wherein the wideband perturbation reference is multiplied by a second gain prior to being combined with the reference signal.

19. The method of any of claims 12-18, wherein the wideband perturbation reference comprises frequencies in the range of 1 Hz to 10 KHz.

20. The method of any of claims 12-19, wherein calculating the impedance of the energy source comprises calculating a Fourier Transform of the electrical response.

21. The method of any of claims 12-20, wherein the wideband perturbation reference is injected over a period of less than five minutes.

22. An energy system, comprising:
an energy source configured to store or discharge electrical energy;
a converter comprising a plurality of switches and configured to supply or withdraw direct current (DC) electricity from the energy source and to output an alternating current (AC) waveform to a load; and
an impedance measurement unit configured to obtain sensed parameters for a harmonic frequency of the AC waveform at the energy source and determine an impedance of the energy source based on the sensed parameters.

23. The energy system of claim 22, wherein the harmonic frequency is a second harmonic frequency.

24. The energy system of claim 22 or 23, wherein the impedance measurement unit is configured to obtain the sensed parameters and determine the impedance of the energy source according to a specified frequency.

25. The energy system of claim 24, wherein the specified frequency is greater than one measurement per minute.

26. The energy system of claim 24, wherein the specified frequency is greater than one measurement per second.

27. The energy system of any of claims 22-26, wherein the converter is configured to adjust the frequency of the AC waveform.

28. The energy system of claim 27, wherein the impedance measurement unit is configured to obtain sensed parameters for each frequency of the AC waveform.

29. A method of determining a state of health of an energy source, the method comprising:
receiving impedance data representing an impedance of an energy source and additional data indicating actual values of one or more parameters of energy source at a time the impedance of energy source was measured;
identifying a set of data structures that each map impedances and tested values of the one or more parameters of a tested energy source to a corresponding capacity of the tested energy sources;
comparing the impedance of the energy source and the actual values of the one or more parameters to corresponding values of each data structure;
identifying, based on the comparison, a closest matching data structure; and
determining the state of health of the energy source based on the capacity corresponding to the closest matching data structure.

30. The method of claim 29, wherein the one or more parameters of the energy source comprise a temperature of the energy source at the time the impedance of the energy source was measured.

31. The method of claim 29 or 30, wherein the one or more parameters of the energy source comprise a state of charge of the energy source at the time the impedance of the energy source was measured.

32. The method of any of claims 29-31, wherein determining the state of health of the energy source comprises comparing the capacity corresponding to the closest matching data structure to a predicted capacity for the energy source based on an age of the energy source.

33. The method of claim 32, wherein determining the state of health of the energy source comprises:
determining that the capacity corresponding to the closest matching data structure is greater than a threshold amount lower than the predicted capacity; and
in response to determining that the capacity corresponding to the closest matching data structure is greater than the threshold amount lower than the predicted capacity, determining that the energy source is degraded.

34. The method of claim 33, further comprising adjusting operation of the energy source or a module that includes the energy source in response to determining that the energy source is degraded.

35. The method of claim 33, further comprising bypassing the energy source or a module than includes the energy source in response to determining that the energy source is degraded.

36. The method of claim 33, further comprising reducing an output of the energy source or a module than includes the energy source in response to determining that the energy source is degraded.

37. The method of any of claims 29-36, further comprising receiving impedance data for multiple frequencies of an AC signal at the energy source.

38. The method of claim 37, further comprising determining a particular degraded condition based on the impedance data for a particular frequency of the multiple frequencies.
